(19) United States
(12) Patent Application Publication
(10) Pub. No.: US 2026/0059744 A1
(43) Pub. Date: Feb. 26, 2026

(54) SEMICONDUCTOR DEVICES

(71) Applicant: Samsung Electronics Co., Ltd., Suwon-si (KR)

(72) Inventors: Seongbin Hong, Suwon-si (KR); Jinwoo Han, Suwon-si (KR)

(21) Appl. No.: 19/248,973

(22) Filed: Jun. 25, 2025

(30) Foreign Application Priority Data
Aug. 22, 2024 (KR) 10-2024-0112640

(51) Int. Cl. H10B 12/00; H10D 30/00; H10D 30/01; H10D 62/10

(52) U.S. Cl. CPC H10B 12/485; H10B 12/09; H10B 12/315; H10B 12/482; H10B 12/50; H10D 30/0191; H10D 30/502; H10D 62/121

(57) ABSTRACT

A semiconductor device may include channels on a first region of a substrate, the channels being spaced apart from each other in a vertical direction perpendicular to an upper surface of the substrate, and the substrate including the first region and a second region, a gate structure at least partially surrounding each of the channels, a bit line in contact with a first end portion of each of the channels, the bit line extending in the vertical direction, a first capacitor on a second end portion of each of the channels, semiconductor patterns arranged in the vertical direction on the second region of the substrate, each of the semiconductor patterns at least partially overlapping a respective one of the channels in a horizontal direction parallel to the upper surface of the substrate, and second capacitors on the semiconductor patterns, respectively.

### CROSS-REFERENCE TO RELATED APPLICATIONS

This application claims priority under 35 U.S.C. § 119 to Korean Patent Application No. 10-2024-0112640, filed on Aug. 22, 2024 in the Korean Intellectual Property Office (KIPO), the disclosure of which is incorporated by reference herein in its entirety.

### BACKGROUND OF THE INVENTION

Example embodiments of the inventive concepts relate to a semiconductor device. More particularly, example embodiments of the inventive concepts relate to a three-dimensional (3D) semiconductor memory device.

A DRAM device may include word lines, bit lines, channels and capacitors. In order to increase the integration density of the DRAM device, it is helpful to efficiently arrange the word lines, the bit lines, the channels and the capacitors.

### SUMMARY OF THE INVENTION

Example embodiments of the inventive concepts provide a semiconductor device having enhanced electrical characteristics.

According to example embodiments of the inventive concepts, there is provided a semiconductor device. The semiconductor device may include channels on a first region of a substrate, the channels being spaced apart from each other in a vertical direction perpendicular to an upper surface of the substrate, and the substrate including the first region and a second region, a gate structure at least partially surrounding each of the channels, a bit line in contact with a first end portion of each of the channels, the bit line extending in the vertical direction, a first capacitor on a second end portion of each of the channels, semiconductor patterns arranged in the vertical direction on the second region of the substrate, each of the semiconductor patterns at least partially overlapping a respective one of the channels in a horizontal direction parallel to the upper surface of the substrate, and second capacitors on the semiconductor patterns, respectively.

According to example embodiments of the inventive concepts, there is provided a semiconductor device. The semiconductor device may include channels on a first region of a substrate, the channels being spaced apart from each other in a vertical direction perpendicular to an upper surface of the substrate, the substrate including the first region and a second region, a gate structure at least partially surrounding each of the channels, a bit line in contact with a first end portion of each of the channels, the bit line extending in the vertical direction, a first capacitor on a second end portion of each of the channels, a first plate electrode structure extending in the vertical direction on the second region of the substrate, semiconductor patterns on opposite sidewalls of the first plate electrode structure in a first direction parallel to the upper surface of the substrate, at least two of the semiconductor patterns being spaced apart from each other in the vertical direction, second capacitors each contacting a respective one of the opposite sidewalls of the first plate electrode structure and on upper and lower surfaces and a sidewall of at least one of the semiconductor patterns, each of the second capacitors extending in the vertical direction and including a first capacitor electrode, a dielectric pattern and a second capacitor electrode, and second plate electrode structures on the opposite sidewalls, respectively, of the first plate electrode structure and on the second region of the substrate, each of the second plate electrode structures extending in the vertical direction and contacting a respective one of the second capacitors.

According to example embodiments of the inventive concepts, there is provided a semiconductor device. The semiconductor device may include channels on a memory cell region of a substrate, the channels being spaced apart from each other in a vertical direction perpendicular to an upper surface of the substrate, and the substrate including the memory cell region and a peripheral circuit region, a gate structure at least partially surrounding each of the channels, a bit line in contact with a first end portion of each of the channels, the bit line extending in the vertical direction, a cell capacitor on a second end portion of each of the channels, a first plate electrode structure extending in the vertical direction on the peripheral circuit region of the substrate, semiconductor patterns on opposite sidewalls of the first plate electrode structure in a horizontal direction parallel to the upper surface of the substrate, at least two of the semiconductor patterns being spaced apart from each other in the vertical direction, and each of the semiconductor patterns at least partially overlapping a respective one of the channels in the horizontal direction, a power capacitor in contact with at least one of the opposite sidewalls of the first plate electrode structure and on upper and lower surfaces and a sidewall of at least one of the semiconductor patterns, the power capacitor extending in the vertical direction and including a first capacitor electrode, a dielectric pattern and a second capacitor electrode, and a second plate electrode structure on one of the opposite sidewalls of the first plate electrode structure and on the peripheral circuit region of the substrate, the second plate electrode structure extending in the vertical direction and contacting the second capacitor electrode of the power capacitor.

The semiconductor device in accordance with example embodiments may include the memory cell region, and the power capacitor may be disposed in the peripheral circuit region using a stacked structure of the memory cell region. Thus, the power capacitor with sufficient capacitance may be disposed in the semiconductor device while using the existing process, which may enhance the electrical characteristics of the semiconductor device.

### BRIEF DESCRIPTION OF THE DRAWINGS

FIGS. 1 to 7 are a plan view, cross-sectional views and a perspective view illustrating a semiconductor device in accordance with example embodiments.

FIG. 8 is a schematic diagram illustrating an electrical connection of the second capacitor structure illustrated in FIG. 7.

FIGS. 9 to 45 are vertical cross-sectional views and horizontal cross-sectional views illustrating a method of manufacturing a semiconductor device in accordance with example embodiments.

FIGS. 46 to 52 are schematic diagrams illustrating electrical connections of second capacitor structures included in the semiconductor device in accordance with example embodiments.

### DETAILED DESCRIPTION

The above and other aspects and features of the semiconductor devices and the methods of manufacturing the same in accordance with example embodiments will become readily understood from the detailed description that follows, with reference to the accompanying drawings. It will be understood that, although the terms “first,” “second,” “third,” etc. may be used herein to describe various materials, layers, regions, pads, electrodes, patterns, structures and/or processes, these various materials, layers, regions, pads, electrodes, patterns, structures and/or processes should not be limited by these terms. Rather, these terms are only used to distinguish one material, layer, region, pad, electrode, pattern, structure or process from another material, layer, region, pad, electrode, pattern, structure or process. Thus, “first”, “second,” “third,” etc. may be used selectively or interchangeably for each material, layer, region, pad, electrode, pattern, structure or process.

Two directions among horizontal directions that are substantially parallel to an upper surface of the substrate, which intersect (or cross) each other, may be referred to as first and second directions D1 and D2, respectively, and a direction substantially vertical (i.e., perpendicular) to the upper surface of the substrate may be referred to as a third direction D3. In example embodiments, the first and second directions D1 and D2 may be substantially perpendicular to each other. Each of the first to third directions D1, D2 and D3 may include not only a direction shown in the drawings but also a direction opposite thereto.

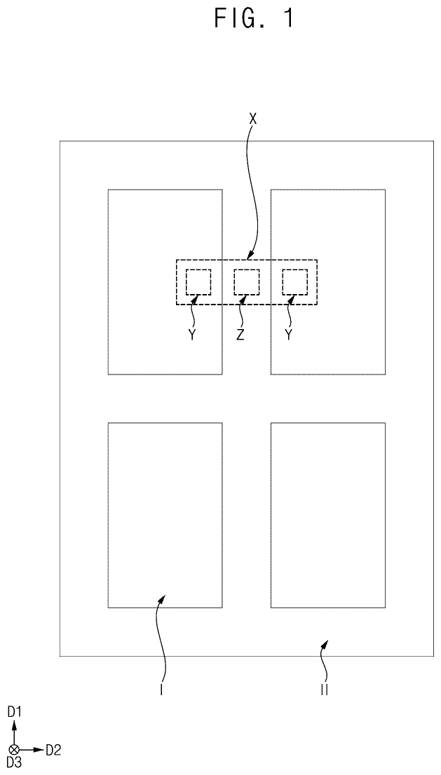

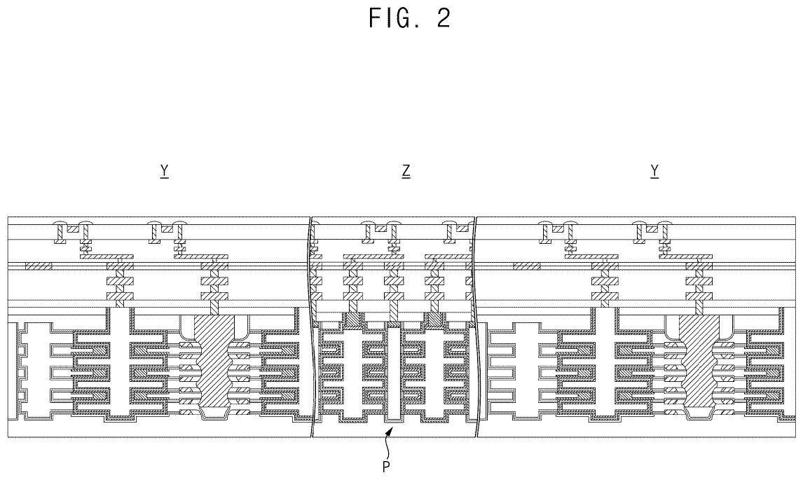

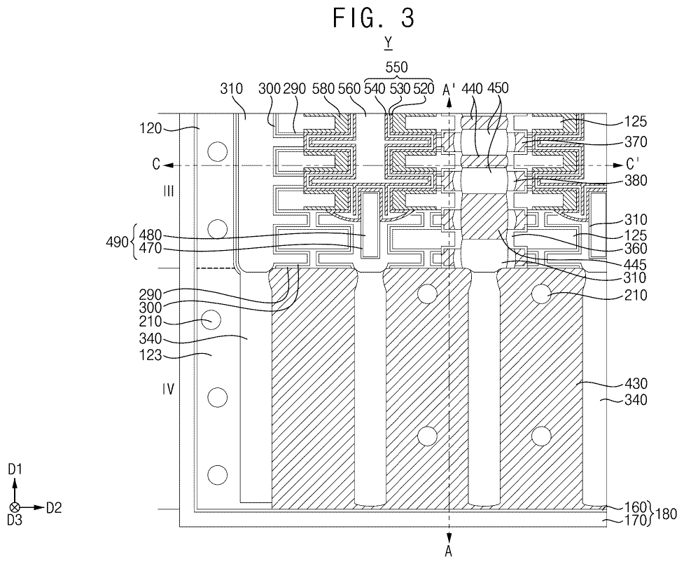

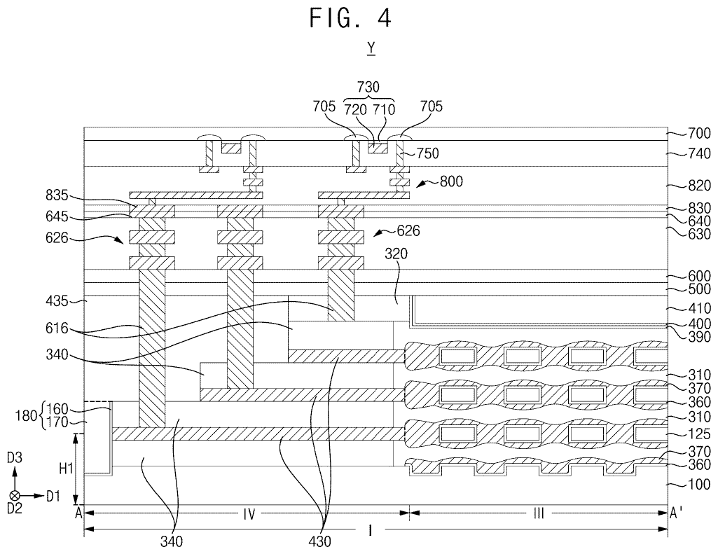

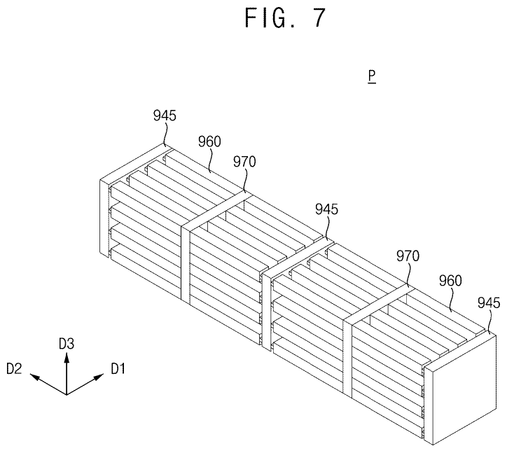

FIGS. 1 to 7 are a plan view, cross-sectional views and a perspective view illustrating a semiconductor device in accordance with example embodiments. Particularly, FIG. 1 is the plan view, FIG. 2 is a vertical cross-sectional view, FIG. 3 is a horizontal cross-sectional view, FIGS. 4 to 6 are vertical cross-sectional views, and FIG. 7 is the perspective view.

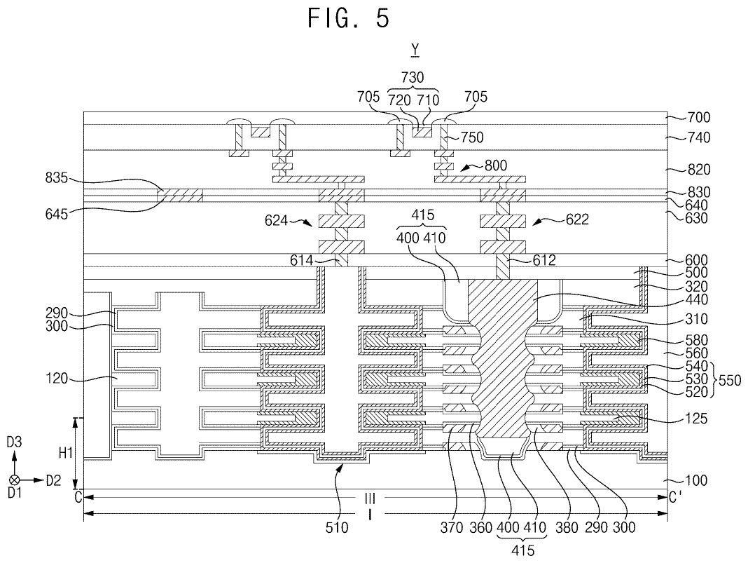

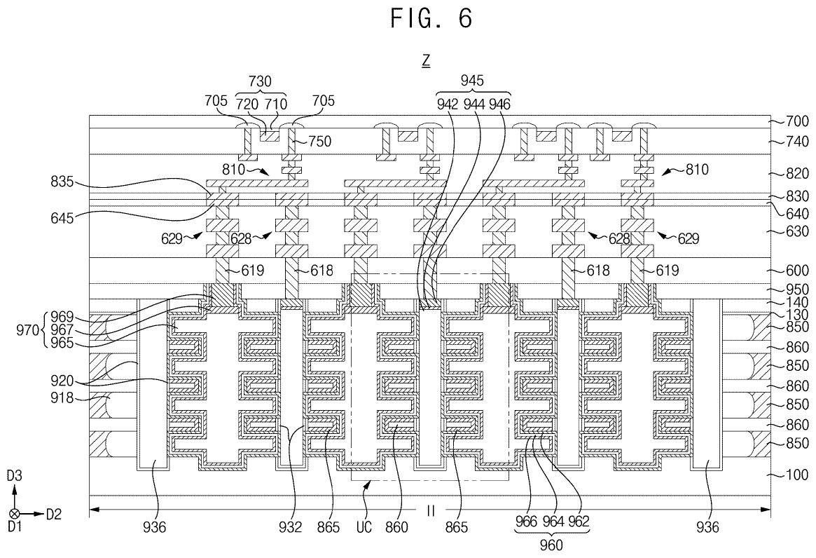

FIG. 1 is a plan view illustrating regions included in the semiconductor device, FIG. 2 is a vertical cross-sectional view of a region X of FIG. 1, which is a schematic diagram showing main elements of the semiconductor device, FIG. 3 is a horizontal cross-sectional view of a region Y of FIG. 1 at a height H1 of FIGS. 4 and 5, FIGS. 4 and 5 are cross-sectional views, respectively, of the region Y of FIG. 1 taken along lines A-A′ and C-C′, respectively, of FIG. 3, FIG. 6 is a vertical cross-sectional view of a region Z of FIG. 1, and FIG. 7 is a perspective view of a region P of FIG. 2, which is a schematic diagram showing main elements of a second capacitor structure included in the semiconductor device.

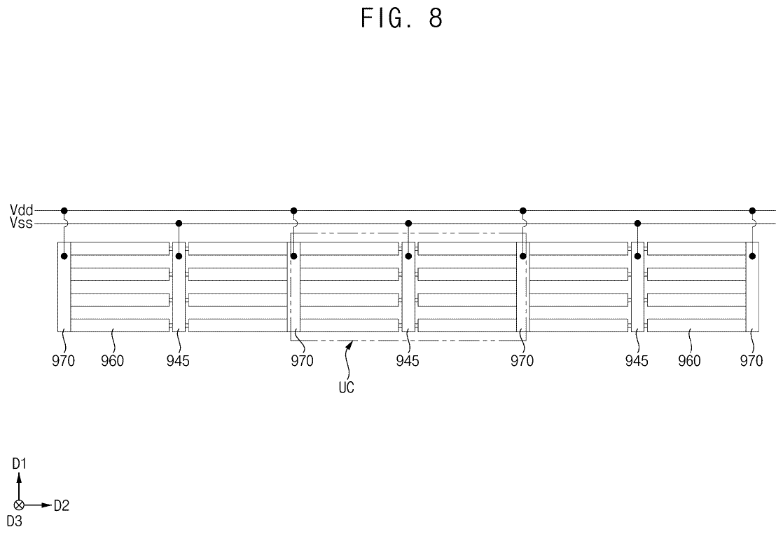

FIG. 8 is a schematic diagram illustrating an electrical connection of the second capacitor structure illustrated in FIG. 7.

Referring to FIGS. 1 to 6, the semiconductor device may include first and second regions I and II.

In example embodiments, the first region I may be a memory cell region in which memory cells are disposed, and the second region II may be a peripheral circuit region in which circuit patterns for applying electrical signals to the memory cells are disposed. The first region I may include memory cell block regions each of which may include memory cells, and the memory cell block regions may be arranged in each of the first and second directions D1 and D2, and may be separated from each other by a first division structure 180.

The first division structure 180 may contact an upper surface of the first region I of the first substrate 100, and may have a lattice shape in a plan view. In example embodiments, the first division structure 180 may include a first division pattern 160 and a second division pattern 170 on (e.g., covering and/or overlapping) a sidewall and a lower surface of the first division pattern 160. The first division pattern 160 may include an insulating nitride, e.g., silicon nitride, and the second division pattern 170 may include an oxide, e.g., silicon oxide.

Each of the memory cell block regions may include third and fourth regions III and IV. The third region III may be a memory cell array region in which a memory cell array including the memory cells is disposed, and the fourth region IV may be a pad region or an extension region in which contact plugs for transferring electrical signals to the memory cell array or conductive pads contacting the contact plugs are disposed.

In example embodiments, the fourth region IV may be disposed at one side or opposite sides in the first direction D1 of the third region III. FIG. 3 shows a portion of the memory cell block region, that is, a portion of each of the third and fourth regions III and IV.

In the specification, each of the first to fourth regions I, II, III and IV may be defined in an inside of the first substrate 100 and/or the second substrate 700 on which the semiconductor device are disposed, or may also be defined in a space over and under the first substrate 100 and/or the second substrate 700.

In example embodiments, the semiconductor device may have a periphery over cell (POC) structure or a cell over periphery (COP) structure. Thus, some of the circuit patterns may be disposed not only in the peripheral circuit region but also over or under the memory cells in the memory cell region. FIGS. 1 to 6 show that the semiconductor device has a POC structure in which some of the circuit patterns are disposed over the memory cells.

In some cases, an upper portion of the memory cell region, that is, a region in which some of the circuit patterns are disposed may be referred to as a core region, and a lower portion of the memory cell region, that is, a region in which the memory cells are disposed may be referred to as a memory cell region.

As the semiconductor device has the POC structure, the peripheral circuit region may have upper and lower portions, which may be referred to as first and second peripheral circuit regions, respectively. In example embodiments, the circuit patterns may be disposed in the first peripheral circuit region, and the second capacitor structure may be disposed in the second peripheral circuit region. The second capacitor structure is discussed in greater detail below.

The memory cell region and the core region may be differentiated from each other by a bonding layer structure including first and second bonding layers 640 and 830, and the first and second peripheral circuit regions may also be differentiated from each other by the bonding layer structure including the first and second bonding layers 640 and 830.

The semiconductor device may include a channel 125, a first gate structure, a bit line 440, a first capacitor structure, a conductive pad 430, first to third contact plugs 612, 614 and 616, and first to third wiring structures 622, 624 and 626 on the first region I of the first substrate 100, and the second capacitor structure, fourth and fifth contact plugs 618 and 619, and fourth and fifth wiring structures 628 and 629 on the second region II of the first substrate 100.

Additionally, the semiconductor device may include a dummy bit line 445, a blocking structure 490, a first division structure 180, a third division structure, a fourth division structure 415, a support pattern 210, a semiconductor layer 120, a first semiconductor pattern 123, a second mask 320, an eighth division pattern 340, an eleventh division pattern 450, a second insulating interlayer 435, and a first capping layer 500 on the first region I of the first substrate 100.

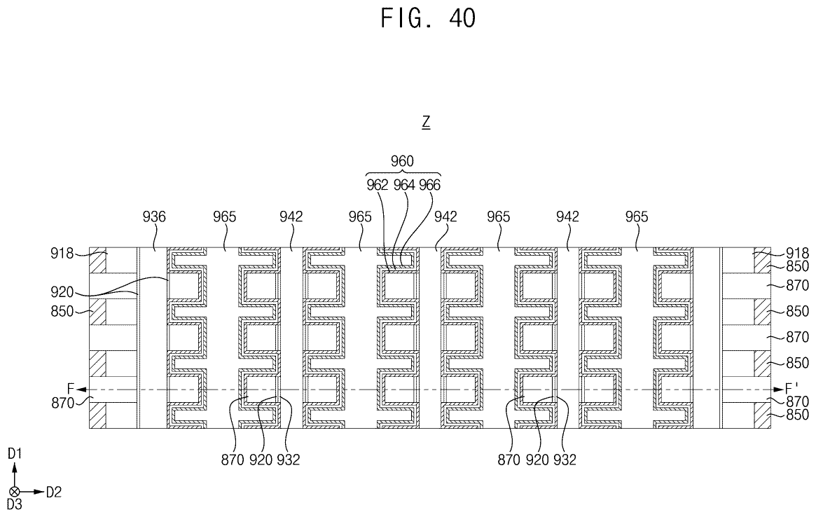

Additionally, the semiconductor device may include a third sacrificial pattern 850, a second semiconductor pattern 860, a fifth insulating pattern 918, a liner 920, a twelfth division pattern 870 (refer to FIG. 40), thirteenth and fifteenth division patterns 932 and 936, an insulating pad layer 130, a first mask layer 140, and a second capping layer 950 on the second region II of the first substrate 100.

Furthermore, the semiconductor device may include a transistor, a sixth contact plug 750, and sixth and seventh wiring structures 800 and 810 under the first and second regions I and II of the second substrate 700.

The semiconductor device may further include third and fourth insulating interlayers 600 and 630 on the first and second regions I and II of the first substrate 100, fifth and sixth insulating interlayers 740 and 820 under the first and second regions of the second substrate 700, and the bonding layer structure may be disposed between the fourth insulating interlayer 630 and the sixth insulating interlayer 820.

Each of the first and second substrates 100 and 700 may include a semiconductor material, e.g., silicon, germanium, silicon-germanium, etc., or a III-V group compound semiconductor, such as GaP, GaAs, GaSb, etc. In example embodiments, each of the first and second substrates 100 and 700 may be a silicon-on-insulator (SOI) substrate or a germanium-on-insulator (GOI) substrate.

The channel 125 may extend in the second direction D2 to a given length on the third region III of the first substrate 100, and a plurality of channels 125 may be spaced apart from each other in the first direction D1 at the same level from the upper surface of the first substrate 100 to form a channel column. As used herein, the term “level” may refer to a height or distance in the third direction D3 (e.g., a vertical direction) from the upper surface of the first substrate 100. In example embodiments, a plurality of channel columns may be spaced apart from each other in the second direction D2 to form a channel array. Additionally, a plurality of channels 125 may be spaced apart from each other in the third direction D3, so that a plurality of channel columns may be spaced apart from each other in the third direction D3 and a plurality of channel arrays may be spaced apart from each other in the third direction D3.

The semiconductor layer 120 may extend in the first direction D1 on each of opposite lateral portions in the second direction D2 of the third region III of the first substrate 100. Additionally, the first semiconductor pattern 123 may extend in the first direction D1 on each of opposite lateral portions in the second direction D2 of the fourth region IV of the first substrate 100, and the first semiconductor pattern 123 may contact and be connected to the semiconductor layer 120. In example embodiments, each of the semiconductor layer 120 and the first semiconductor pattern 123 may be disposed at a height the same as that of a corresponding one of the channels 125 from the upper surface of the first substrate 100 (e.g., in the third direction D3).

The second semiconductor pattern 860 may extend in the second direction D2 to a given length on the second region II of the first substrate 100, and a plurality of second semiconductor patterns 860 may be spaced apart from each other in the first direction D1 to form a second semiconductor pattern column. In example embodiments, a plurality of second semiconductor pattern columns may be spaced apart from each other in the second direction D2 to form a second semiconductor pattern array. Additionally, a plurality of second semiconductor patterns 860 may be spaced apart from each other in the third direction D3, so that a plurality of second semiconductor pattern columns may be spaced apart from each other in the third direction D3 and a plurality of second semiconductor pattern arrays may be spaced apart from each other in the third direction D3. In example embodiments, each of the second semiconductor patterns 860 may be disposed at a height the same as that of a corresponding one (i.e., a respective one) of the channels 125 from the upper surface of the first substrate 100 (e.g., in the third direction D3). For example, ones of the second semiconductor patterns 860 may be disposed (i.e., arranged) in the third direction D3 on the second region II of the first substrate 100, and the ones of the second semiconductor patterns 860 may overlap respective ones of the channels 125 in the horizontal direction (e.g., see FIG. 2). For example, the second semiconductor patterns 860 may be on opposite sidewalls of the second plate electrode structure 945 (e.g., in the second direction D2).

Each of the channel 125, the semiconductor layer 120 and the first and second semiconductor patterns 123 and 860 may include the same material, e.g., a semiconductor material such as silicon.

The first gate structure may surround an end portion in the second direction D2 of the channel 125, and may include a first gate electrode 370, a first gate insulating pattern 360 and a gate mask 380. In example embodiments, the first gate structure may extend in the first direction D1 and surround end portions of the channels 125 in each of the channel columns on the third region III of the first substrate 100, and a plurality of first gate structures may be spaced apart from each other in the second direction D2. For example, the first gate structure may at least partially surround ones of the channels 125 that are disposed in the third direction D3. Each of the first gate structures may serve as a word line of the semiconductor device. As used herein, “an element A surrounds an element B” (or similar language) means that the element A is at least partially around the element B but does not necessarily mean that the element A completely encloses the element B.

The first gate insulating pattern 360 may be on (e.g., may cover and/or overlap) lower and upper surfaces and opposite sidewalls in the first direction D1 of the end portion of the channel 125. The first gate insulating pattern 360 may include an oxide, e.g., silicon oxide.

The first gate electrode 370 may be on (e.g., may cover and/or overlap) lower and upper surfaces and opposite sidewalls in the first direction D1 of a portion of the first gate insulating pattern 360. In example embodiments, the first gate electrode 370 may extend in the first direction D1, and may be on (e.g., may cover and/or overlap) the portions of ones of the first gate insulating patterns 360 disposed in the first direction D1. The first gate electrode 370 may include a conductive material, e.g., a metal, a metal nitride, a metal silicide, etc.

The gate mask 380 may be on (e.g., may cover and/or overlap) lower and upper surfaces and opposite sidewalls in the first direction D1 of a portion of the first gate insulating pattern 360, and may contact a sidewall in the second direction D2 of the first gate electrode 370. The gate mask 380 may include an insulating nitride, e.g., silicon nitride.

The conductive pad 430 may extend in the first direction D1 on the fourth region IV of the first substrate 100, and a plurality of conductive pads 430 may be spaced apart from each other in the second direction D2. In example embodiments, at least a portion of the conductive pad 430 may be disposed at the same height as the first gate electrode 370 (e.g., in the third direction D3), and may contact a sidewall in the first direction D1 of the first gate electrode 370 to be electrically connected thereto. In example embodiments, the conductive pad 430 may overlap the first gate structure and the channel 125 in the first direction D1. As used herein, “an element A overlaps an element B in a direction X” (or similar language) means that there is at least one straight line that extends in the direction X and intersects both the elements A and B.

In example embodiments, a plurality of conductive pads 430 may be spaced apart from each other in the third direction D3, and lengths in the first direction D1 of the conductive pads 430 may decrease from a lowermost one to an uppermost one thereof in a stepwise manner. Thus, the conductive pads 430 disposed in the third direction D3 may form a staircase structure.

The conductive pad 430 may include a conductive material, e.g., a metal, a metal nitride, a metal silicide, doped polysilicon, etc.

In example embodiments, the third division structure may include first and second insulating patterns 290 and 300, and a seventh division pattern 310.

The third division structure may be disposed on the first region I of the first substrate 100, and may be in (e.g., may fill) spaces between the first gate structures, between the channels 125, between the semiconductor layers 120 that are stacked in the third direction D3, between the upper surface of the first substrate 100 and a lowermost one of the first gate structures, between the upper surface of the first substrate 100 and each of a lowermost one of the channels 125 and a lowermost one of the semiconductor layers 120, and between the second mask 320 and each of an uppermost one of the first gate structures, an uppermost one of the channels 125 and an uppermost one of the semiconductor layers 120. Additionally, the third division structure may be in (e.g., may fill) spaces between ones of the channels 125 neighboring (i.e., adjacent) in the second direction D2, and between the channel 125 and the semiconductor layer 120. Furthermore, the third division structure may be disposed between ones of the channels 125 neighboring in the first direction D1 on the first region I of the first substrate 100.

The first and second insulating patterns 290 and 300 may be sequentially stacked on a surface of the channel 125, and the seventh division pattern 310 may be disposed on the second insulating pattern 300 and may be in (e.g., may fill) other portions of the spaces.

The first insulating pattern 290 and the seventh division pattern 310 may include an oxide, e.g., silicon oxide, and the second insulating pattern 300 may include an insulating nitride, e.g., silicon nitride.

The eighth division pattern 340 may be disposed on the fourth region IV of the first substrate 100, and may be in (e.g., may fill) spaces between the conductive pads 430 and between the first semiconductor patterns 123 that are stacked in the third direction D3, between the upper surface of the first substrate 100 and each of a lowermost one of the conductive pads 430 and a lowermost one of the first semiconductor patterns 123, and between the second mask 320 and each of an uppermost one of the conductive pads 430 and an uppermost one of the semiconductor patterns 123.

Additionally, the eighth division pattern 340 may be disposed between ones of the conductive pads 430 neighboring in the first direction D1 and between the semiconductor patterns 123 and the conductive pads 430 on the fourth region IV of the first substrate 100.

In example embodiments, lengths in the first direction D1 of the eighth division patterns 340 disposed in the third direction D3 may decrease from a lowermost one to an uppermost one in a stepwise manner, and thus a stack structure including the eighth division patterns 340 may be a staircase structure. In example embodiments, one of the eighth division patterns 340 on a corresponding one of the conductive pads 430 at each level and the corresponding one of the conductive pads 430 may collectively form a step layer, and a sidewall in the first direction D1 of each of the eighth division patterns 340 may be aligned with (e.g., may be collinear with) a sidewall in the first direction D1 of the corresponding one of the conductive pads 430 in the third direction D3.

The eighth division pattern 340 may include an insulating nitride, e.g., silicon nitride.

The support pattern 210 may be disposed on the first region I of the first substrate 100, and may extend through the semiconductor layers 120, the third division structure, the eighth division pattern 340 and the conductive pads 430 to contact the upper surface of the first substrate 100. A plurality of support patterns 210 may be spaced apart from each other in the first direction D1 on each of opposite lateral portions in the second direction D2 of the third region III of the first substrate 100, and a plurality of support patterns 210 may be spaced apart from each other in each of the first and second directions D1 and D2 on the fourth region IV of the first substrate 100.

The support pattern 210 may include an insulating nitride, e.g., silicon nitride, and may be merged with the eighth division pattern 340.

The second mask 320 may be disposed on the third division structure and the eighth division pattern 340 on the first region I of the first substrate 100. However, the eighth division pattern 340 may be on (e.g., may cover and/or overlap) a sidewall of the second mask 320, and thus an upper surface of the second mask 320 may be coplanar with an upper surface of the eighth division pattern 340. The second mask 320 may include an insulating nitride, e.g., silicon nitride.

The second insulating interlayer 435 may be disposed on the eighth division pattern 340 on the fourth region IV of the first substrate 100. In example embodiments, an upper surface of the second insulating interlayer 435 may be coplanar with the upper surface of the second mask 320. The second insulating interlayer 435 may include an oxide, e.g., silicon oxide.

The fourth division structure 415 may be disposed between the ones of the channels 125 neighboring in the second direction D2 on the first region I of the first substrate 100. In example embodiments, the fourth division structure 415 may extend in the first direction D1 on each of the second and third regions II and III of the first substrate 100, and a plurality of fourth division structures 415 may be spaced apart from each other in the second direction D2. In example embodiments, an upper surface of the fourth division structure 415 may be coplanar with the upper surface of the second mask 320.

The fourth division structure 415 may include a ninth division pattern 410 and a fourth insulating pattern 400 on (e.g., covering and/or overlapping) a sidewall and a lower surface of the ninth division pattern 410. The fourth insulating pattern 400 may include an insulating nitride, e.g., silicon nitride, and the ninth division pattern 410 may include an oxide, e.g., silicon oxide.

The bit line 440 may extend in the third direction D3 partially through the fourth division structure 415 extending in the first direction D1 on the third region III of the first substrate 100, and a plurality of bit lines 440 may be spaced apart from each other in the first direction D1. The eleventh division pattern 450 including an oxide, e.g., silicon oxide, may extend partially through the fourth division structure 415 between ones of the bit lines 440 neighboring in the first direction D1, so that the bit lines 440 may be separated from each other by the eleventh division pattern 450. The dummy bit line 445 may be disposed on a portion of the third region III adjacent to the fourth region IV of the first substrate 100.

In example embodiments, each of the bit line 440 and the dummy bit line 445 may contact ones of the channels 125 that are disposed in the third direction D3 at each of opposite sides in the second direction D2 of each of the bit line 440 and the dummy bit line 445. For example, each of the bit line 440 and the dummy bit line 445 may be in contact with end portions of ones of the channels 125 that are disposed in the third direction D3. Each of the bit line 440 and the dummy bit line 445 may contact sidewalls in the second direction D2 of the first gate insulating pattern 360 and the gate mask 380 that may surround the end portion of each of the channels 125.

In example embodiments, each of the bit line 440 and the dummy bit line 445 may include, e.g., polysilicon doped with n-type impurities. In other example embodiments, each of the bit line 440 and the dummy bit line 445 may include, e.g., a metal, a metal nitride, a metal silicide, etc.

The blocking structure 490 may extend through the third division structure between the ones of the channels 125 neighboring in the second direction D2 on a portion of the third region III adjacent to the fourth region IV of the first substrate 100, and may contact the upper surface of the first substrate 100. The blocking structure 490 may be disposed at an opposite side of the bit line 440 in the second direction D2 with respect to the channel 125. In example embodiments, the blocking structure 490 may have a shape of, e.g., a polygon such as a rectangle in a plan view, however, the inventive concepts are not limited thereto.

In example embodiments, the blocking structure 490 may include a second blocking pattern 480 extending in the third direction D3 and a first blocking pattern 470 on (e.g., covering and/or overlapping) a sidewall and a lower surface of the second blocking pattern 480. The first blocking pattern 470 may include an insulating nitride, e.g., silicon nitride, and the second blocking pattern 480 may include an oxide, e.g., silicon oxide.

The first capacitor structure may include a first capacitor 550 and a first plate electrode 560, and the first capacitor 550 may include first and second capacitor electrodes 520 and 540 and a first dielectric pattern 530.

In example embodiments, the first capacitor electrode 520, the first dielectric pattern 530 and the second capacitor electrode 540 may be sequentially stacked in spaces between the ones of the channels 125 stacked in the third direction D3, between the lowermost one of the channels 125 and the upper surface of the first substrate 100 and between the uppermost one of the channels 125 and the second mask 320 on the third region III of the first substrate 100, and the first plate electrode 560 may be in (e.g., may fill) a remaining portion of the spaces and a space between the ones of the channels 125 neighboring in the second direction D2.

Thus, the first plate electrode 560 may include a first vertical extension portion extending in the third direction D3 and a first horizontal extension portion extending from each of opposite sidewalls of the first vertical extension portion in the second direction D2. A plurality of first horizontal extension portions may be spaced apart from each other from each of the opposite sidewalls of the first vertical extension portion in the third direction D3. Each of the first capacitor 550 and the first plate electrode 560 may extend in the first direction D1 on the third region III of the first substrate 100. The first plate electrode 560 may include, e.g., silicon-germanium doped with impurities, or undoped silicon-germanium.

In example embodiments, the first capacitor structure may extend through the first capping layer 500 and the third division structure, and may contact a sidewall in the first direction D1 of the blocking structure 490. Thus, the first capacitor structure may be disposed at an opposite side of the bit line 440 in the second direction D2 with respect to the channel 125.

A first metal silicide pattern 580 may be disposed at a portion of each of the channels 125 contacting the first capacitor electrode 520. For example, the first metal silicide pattern 580 may be between each of the channels 125 and the first capacitor 550. The first metal silicide pattern 580 may include a metal silicide, e.g., titanium silicide, tantalum silicide, etc.

The word line (e.g., the first gate structure) and the bit line 440 extending in the first and second directions D1 and D2, respectively, the channel 125 that may be surrounded by the word line and may contact and be electrically connected to the bit line 440, and the first capacitor 550 electrically connected to the channel 125 on the third region III of the first substrate 100 may collectively form the memory cell, and a plurality of memory cells may be disposed in each of the first to third directions D1, D2 and D3 on the third region III of the first substrate 100.

The first capping layer 500 may be disposed on the second mask 320, the second insulating interlayer 435 and the fourth division structure 415 on the first region I of the first substrate 100, and may be on (e.g., may cover and/or overlap) a sidewall of an upper portion of the first capacitor structure. The first capping layer 500 may include an insulating nitride, e.g., silicon nitride.

The third sacrificial pattern 850 and the fifth insulating pattern 918 may be disposed between ones of the second semiconductor patterns 860 neighboring in the third direction D3 on the second region II of the first substrate 100, on an upper surface of an uppermost one of the second semiconductor patterns 860 and between the upper surface of the first substrate 100 and a lower surface of a lowermost one of the second semiconductor patterns 860. Sidewalls of the third sacrificial pattern 850 and the fifth insulating pattern 918 in the second direction D2 may contact each other. The third sacrificial pattern 850 and the fifth insulating pattern 918 may overlap in the third direction D3 ones of the second semiconductor patterns 860 disposed at each of opposite edges in the second direction D2 among the semiconductor patterns 860 disposed in each of the first and second directions D1 and D2.

The third sacrificial pattern 850 may include a material having an etching selectivity with respect to the second semiconductor pattern 860, e.g., silicon-germanium, and the fifth insulating pattern 918 may include an oxide, e.g., silicon oxide.

The insulating pad layer 130 and the first mask layer 140 may be sequentially stacked in the third direction D3 on upper surfaces of an uppermost one of the third sacrificial patterns 850 and an uppermost one of the fifth insulating patterns 918. A plurality of first mask layers 140 may be spaced apart from each other in each of the first and second directions D1 and D2, and may overlap the second semiconductor patterns 860 in the third direction D3.

The insulating pad layer 130 may include an oxide, e.g., silicon oxide, and the first mask layer 140 may include an insulating nitride, e.g., silicon nitride.

Referring to FIG. 40, a plurality of twelfth division patterns 870 may be spaced apart from each other in each of the first and second directions D1 and D2 on the second region II of the first substrate 100.

The twelfth division pattern 870 may extend in the third direction D3, and some of the twelfth division patterns 870, e.g., ones of the twelfth division patterns 870 disposed at each of opposite edges in the second direction D2 may contact sidewalls in the first direction D1 of each of the third sacrificial pattern 850, the fifth insulating pattern 918, the second semiconductor pattern 860, the insulating pad layer 130 and the first mask layer 140.

The twelfth division pattern 870 may include a material having an etching selectivity with respect to the fifth insulating pattern 918, e.g., an insulating nitride, such as silicon nitride.

Referring back to FIGS. 1 to 6 and FIG. 40, the fifteenth division pattern 936 may extend in the first direction D1 on the second region II of the first substrate 100, and a plurality of fifteenth division patterns 936 may be spaced apart from each other in the second direction D2. A sidewall and a lower surface of the fifteenth division pattern 936 may have the liner 920 thereon (e.g., may be covered and/or overlapped by the liner 920).

The fifteenth division pattern 936 may extend in the third direction D3, and the liner 920 on a sidewall of the fifteenth division pattern 936 may contact sidewalls in the second direction D2 of the fifth insulating patten 918, the second semiconductor pattern 860, the insulating pad layer 130 and the first mask layer 140 stacked in the third direction D3, and a sidewall in the second direction D2 of the twelfth division pattern 870.

The fifteenth division pattern 936 may include an oxide, e.g., silicon oxide, and the liner 920 may include an insulating nitride, e.g., silicon nitride.

The second capacitor structure may include a second capacitor 960 and second and third plate electrode structures 945 and 970 on the second region II of the first substrate 100. In other words, the second plate electrode structure 945, the third plate electrode structure 970, and the second capacitor 960 on the second region II of the first substrate 100 may be included in the second capacitor structure. For example, a plurality of second capacitor structures may be arranged in the second direction D2 on the second region II of the first substrate 100.

The second capacitor 960 may include a third capacitor electrode 962, a second dielectric pattern 964 and a fourth capacitor electrode 966 sequentially stacked. The second plate electrode structure 945 may include first to third conductive patterns 942, 944 and 946 sequentially stacked in the third direction D3. The third plate electrode structure 970 may include fourth to sixth conductive patterns 965, 967 and 969 sequentially stacked in the third direction D3.

The first conductive pattern 942 included in the second plate electrode structure 945 may extend in the first and third directions D1 and D3 on the second region II of the first substrate 100. A plurality of first conductive patterns 942 may be spaced apart from each other in the second direction D2 between ones of the fifteenth division patterns 936 neighboring in the second direction D2. In example embodiments, an upper surface of the first conductive pattern 942 may be higher than a lower surface of the first mask layer 140 (e.g., relative to the upper surface of the first substrate 100 in the third direction D3), however, the inventive concepts are not limited thereto.

The thirteenth division pattern 932 and the liner 920 may be stacked in the second direction D2 on a sidewall in the second direction D2 of the first conductive pattern 942, particularly, on a sidewall of a first portion of the first conductive pattern 942 facing the twelfth division pattern 870 and a sidewall of a second portion of the first conductive pattern 942 overlapping the second semiconductor pattern 860 in the second direction D2. Thus, a structure including the thirteenth division pattern 932 and the liner 920 on the sidewall of the first portion of the first conductive pattern 942 may extend in the third direction D3, and a plurality of structures including the thirteenth division pattern 932 and the liner 920 on the sidewall of the second portion of the first conductive pattern 942 may be spaced apart from each other in the third direction D3. For example, the structure including the thirteenth division pattern 932 and the liner 920 may be between (e.g., in the second direction D2) and may contact a sidewall of the second plate electrode structure 945 (e.g., a sidewall of the first conductive pattern 942) and a sidewall of each of the second semiconductor patterns 860. For example, the thirteenth division pattern 932 and the liner 920 may be sequentially stacked in the second direction D2 on the sidewall of the second plate electrode structure 945 (e.g., the sidewall of the first conductive pattern 942).

The thirteenth division pattern 932 and the liner 920 may also be disposed on a sidewall of a third portion of the first conductive pattern 942 facing the first mask layer 140, and may contact a sidewall in the second direction D2 of the first mask layer 140. Additionally, the thirteenth division pattern 932 and the liner 920 may be disposed on a lower surface and a lower sidewall of the first conductive pattern 942, and may contact the upper surface of the first substrate 100.

The thirteenth division pattern 932 may include an oxide, e.g., silicon oxide, and the liner 920 may include an insulating nitride, e.g., silicon nitride. Thus, the thirteenth division pattern 932 and the liner 920 sequentially stacked may collectively form an insulating layer structure. As used herein, the thirteenth division pattern 932 and the liner 920 may also be referred to as a first insulating layer and a second insulating layer, respectively, of the insulating layer structure.

In example embodiments, the first conductive pattern 942 may include, e.g., polysilicon doped with impurities, the second conductive pattern 944 may include a metal silicide, e.g., tungsten silicide, titanium silicide, etc., and the third conductive pattern 946 may include a metal, e.g., tungsten. In other example embodiments, the first to third conductive patterns 942, 944 and 946 may include a metal, e.g., tungsten, and may be merged to each other, and the second plate electrode structure 945 may have a single-layer structure.

The third capacitor electrode 962 included in the second capacitor 960 may contact a portion of a sidewall of the first conductive pattern 942 in the second direction D2 on the second region II of the first substrate 100, particularly, a sidewall of a portion of the first conductive pattern 942 overlapping the fifth insulating pattern 918 in the second direction D2, upper and lower surfaces and a sidewall in the second direction D2 of the second semiconductor pattern 860, and opposite sidewalls in the first direction D1 and a sidewall in the second direction D2 of the twelfth division pattern 870. Additionally, the third capacitor electrode 962 may contact upper and lower surfaces of the thirteenth division pattern 932 and the liner 920 on the sidewall in the second direction D2 of the first conductive pattern 942.

A second metal silicide pattern 865 may be disposed on a portion of the second semiconductor pattern 860 contacting the third capacitor electrode 962. For example, the second metal silicide pattern 865 may be between each of the second semiconductor patterns 860 and a corresponding one (i.e., a respective one) of the second capacitors 960. The second metal silicide pattern 865 may include a metal silicide, e.g., titanium silicide, tantalum silicide, etc.

In example embodiments, the second capacitor 960 may extend in the first direction D1 between ones of the second plate electrode structures 945 neighboring each other in the second direction D2, and may extend in the third direction D3.

Each of the first to fourth capacitor electrodes 520, 540, 962 and 966 may include a metal, e.g., titanium, tantalum, etc., or a metal nitride, e.g., titanium nitride, tantalum nitride, etc. Each of the first and second dielectric patterns 530 and 964 may include a high-k metal oxide, e.g., hafnium oxide, zirconium oxide, etc.

The third plate electrode structure 970 may be in (e.g., may fill) a space defined by the second capacitor 960, and may extend in the first direction D1 on the second region II of the first substrate 100. Thus, the third plate electrode structure 970 may contact the fourth capacitor electrode 966 included in the second capacitor 960. For example, a pair of third plate electrode structures 970 may be on opposite sidewalls, respectively, of the second plate electrode structure 945 (e.g., in the second direction D2) and may be on the second region II of the first substrate 100.

In example embodiments, the fourth conductive pattern 965 included in the third plate electrode structure 970 may include a second vertical extension portion extending in the third direction D3 and a second horizontal extension portion extending in the second direction D2 from each of opposite sidewalls of the second vertical extension portion. A plurality of second horizontal extension portions of the fourth conductive pattern 965 may be spaced apart from each other in the third direction D3 from each of the opposite sidewalls of the second vertical extension portion. In other words, the third plate electrode structure 970 (e.g., the fourth conductive pattern 965) may include a second vertical extension portion extending in the third direction D3, and second horizontal extension portions spaced apart from each other in the third direction D3 and extending in the second direction D2.

In example embodiments, a portion of the second capacitor 960 on a sidewall of each of the second horizontal extension portions of the fourth conductive pattern 965 may contact a sidewall of the first conductive pattern 942 included in the second plate electrode structure 945, and may be electrically connected to the first conductive pattern 942.

In example embodiments, each of the second horizontal extension portions of the fourth conductive pattern 965 may be disposed between ones of the second semiconductor patterns 860 neighboring each other in the third direction D3. Thus, each of the second horizontal extension portions of the fourth conductive pattern 965 may at least partially overlap corresponding ones of the second semiconductor patterns 860 in the third direction D3.

The fifth and sixth conductive patterns 967 and 969 may be stacked in the third direction D3 on an upper surface of the fourth conductive pattern 965. In example embodiments, an upper surface of the fifth conductive pattern 967 may be lower than a lower surface of the first mask layer 140 (e.g., relative to the upper surface of the first substrate 100 in the third direction D3), however, the inventive concepts are not limited thereto.

The fourth conductive pattern 965 may include, e.g., polysilicon doped with impurities, or silicon-germanium doped with impurities, the fifth conductive pattern 967 may include a metal silicide, e.g., tungsten silicide, titanium silicide, etc., or a compound of a metal and silicon-germanium, e.g., tungsten silicon-germanium, titanium silicon-germanium, etc., and the sixth conductive pattern 969 may include a metal, e.g., tungsten.

The second capping layer 950 may be disposed on an upper surface of the first mask layer 140, uppermost surfaces of the liner 920 and the thirteenth division pattern 932, and upper surfaces of the twelfth and fifteenth division patterns 870 and 936 on the second region II of the first substrate 100, and may be on (e.g., may cover and/or overlap) an upper sidewall of the second capacitor 960. The second capping layer 950 may include an insulating nitride, e.g., silicon nitride.

The third and fourth insulating interlayers 600 and 630, the first and second bonding layers 640 and 830, the sixth and fifth insulating interlayers 820 and 740, and the second substrate 700 may be sequentially stacked in the third direction D3 on the first and second capping layers 500 and 950, and the first and second capacitor structures on the first and second regions I and II of the first substrate 100.

The first contact plug 612 may extend through the third insulating interlayer 600 and the first capping layer 500 and may contact an upper surface of the bit line 440, the second contact plug 614 may extend through the third insulating interlayer 600 and may contact an upper surface of the first plate electrode 560 included in the first capacitor structures, the third contact plug 616 may extend through the third insulating interlayer 600, the first capping layer 500, the second mask 320 and the eighth division pattern 340 or the third insulating interlayer 600, the first capping layer 500 and the second insulating interlayer 435 and may contact an upper surface of the conductive pad 430.

The fourth contact plug 618 may extend through the third insulating interlayer 600 and the second capping layer 950 and may contact an upper surface of the third conductive pattern 946 included in the second plate electrode structure 945, and the fifth contact plug 619 may extend through the third insulating interlayer 600 and may contact an upper surface of the sixth conductive pattern 969 included in the third plate electrode structure 970.

The first to fifth wiring structures 622, 624, 626, 628 and 629 may be disposed in the fourth insulating interlayer 630 and may contact upper surfaces of the first to fifth contact plugs 612, 614, 616, 618 and 619, respectively. The first bonding layer 640 may include the first bonding pad 645 therein, and the second bonding layer 830 may include the second bonding pad 835 therein. The first and second bonding pads 645 and 835 may contact each other. Each of the first bonding pads 645 may contact a corresponding one of the first to fifth wiring structures 622, 624, 626, 628 and 629, and may be electrically connected to the corresponding one of the first to fifth wiring structures 622, 624, 626, 628 and 629.

The sixth and seventh wiring structures 800 and 810 may be disposed on the first and second regions I and II of the first substrate 100, respectively, and may be have the sixth insulating interlayer 820 thereon (e.g., may be covered and/or overlapped by the sixth insulating interlayer 820). The sixth and seventh wiring structures 800 and 810 may contact a corresponding one of the second bonding pads 835, and may be electrically connected to the corresponding one of the second bonding pads 835. The sixth contact plugs 750 may be disposed in the fifth insulating interlayer 740, and may contact corresponding ones of the sixth and seventh wiring structures 800 and 810, respectively.

A second gate structure 730 including a second gate insulating pattern 710 and a second gate electrode 720 may be disposed under the first region I of the second substrate 700, and impurity regions 705 may be disposed at a lower portion of the second substrate 700 adjacent to the second gate structure 730. The second gate structure 730 and the impurity regions 705 may collectively form the transistor.

In the semiconductor device, the memory cells may be disposed in the memory cell region, and the second capacitor structure that may have a similar structure to the first capacitor structure may be disposed at a lower portion of the peripheral circuit region.

That is, the first capacitor 550 included in the first capacitor structure on the first region I of the first substrate 100 may include the first capacitor electrode 520, the first dielectric pattern 530 and the second capacitor electrode 540 stacked on a surface of the channel 125 at each level, and the first metal silicide pattern 580 may be disposed on a portion of the channel 125 contacting the first capacitor electrode 520. For example, the bit line 440 may be on a first end portion of ones of the channels 125 that are disposed in the third direction D3, and the first capacitor 550 may be on a second end portion of the ones of the channels 125 opposite the respective first end portion (e.g., opposite in the second direction D2). The second capacitor 960 included in the second capacitor structure on the second region II of the first substrate 100 may include the third capacitor electrode 962, the second dielectric pattern 964 and the fourth capacitor electrode 966, and the second metal silicide pattern 865 may be disposed on a portion of the second semiconductor pattern 860 contacting the third capacitor electrode 962. Thus, the first and second capacitors 550 and 960 may at least partially overlap each other in the horizontal direction.

Portions of the first capacitor 550 on the surfaces of the channels 125 at a plurality of levels, respectively, may be connected to each other at a sidewall of the seventh division pattern 310, and thus the first capacitor 550 may extend in the third direction D3. Similarly, portions of the second capacitor 960 on the surfaces of the second semiconductor patterns 860 at a plurality of levels, respectively, may be connected to each other at a sidewall of the first conductive pattern 942, and thus the second capacitor 960 may extend in the third direction D3. In other words, as used herein, it may be interpreted that the second capacitor 960 extends in the third direction D3 along ones of the second semiconductor patterns 860 disposed in the third direction D3. For example, when it is interpreted that the second capacitor 960 extends in the third direction D3 along ones of the second semiconductor patterns 860 disposed in the third direction D3, a pair of second capacitors 960 may be on opposite sidewalls, respectively, of the second plate electrode structure 945 (e.g., in the second direction D2). The pair of second capacitors 960 may each contact a respective one of the opposite sidewalls of the second plate electrode structure 945 and may be on upper and lower surfaces and a sidewall of each of ones of the second semiconductor patterns 860.

However, as used herein, it may also be interpreted that at the first capacitor 550 extending in the third direction D3, a portion on the surface of each of the channels 125 may be referred to as the first capacitor 550, and a plurality of first capacitors 550 may be connected to each other in the third direction D3. Similarly, as used herein, it may be also interpreted that at the second capacitor 960 extending in the third direction D3, a portion on the surface of each of the second semiconductor patterns 860 may be referred to as the second capacitor 960, and a plurality of the second capacitors 960 may be connected to each other in the third direction D3. In other words, as used herein, it may be interpreted that a plurality of second capacitors 960 are arranged in the third direction D3 and are on ones of the second semiconductor patterns 860 disposed in the third direction D3, respectively. Said another way, as used herein, it may be interpreted that the second capacitor 960 extends in the third direction D3 along ones of the second semiconductor patterns 860 disposed in the third direction D3, or it may be interpreted that a plurality of second capacitors 960 are arranged in the third direction D3 and are on ones of the second semiconductor patterns 860 disposed in the third direction D3, respectively. For example, when it is interpreted that a plurality of second capacitors 960 are arranged in the third direction D3, the plurality of second capacitors 960 arranged in the third direction D3 may be physically and/or electrically connected to each other, first ones of the plurality of second capacitors 960 may be on a first sidewall of the second plate electrode structure 945, and second ones of the plurality of second capacitors 960 may be on a second sidewall of the second plate electrode structure 945 opposite the first sidewall (e.g., in the second direction D2).

Portions of the second capacitor 960 on surfaces of the horizontal extension portions, respectively, of the third plate electrode structure 970 extending in the first direction D1 may be connected to each other at sidewalls of the twelfth division patterns 870, and thus the second capacitor 960 may extend in the first direction D1. However, as used herein, it may also be interpreted that only the portion of the second capacitor 960 on the surface of each of the horizontal extension portions of the third plate electrode structure 970 may be referred to as the second capacitor 960, and a plurality of second capacitors 960 may be connected to each other in the first direction D1. For example, ones of the second capacitors 960 may be arranged in the first direction D1 and may be connected to each other in the first direction D1 (e.g., may be physically and/or electrically connected to each other).

In example embodiments, the first capacitor 550 included in the first capacitor structure may be a cell capacitor for data storage, and the second capacitor 960 included in the second capacitor structure may be a power capacitor. The second capacitor 960 may include, e.g., a decoupling capacitor for eliminating noise, or a pumping capacitor included in a pumping circuit.

Referring to FIGS. 7 and 8, the second capacitor structure may include a unit capacitor structure UC including the second plate electrode structure 945 extending in the first direction D1, the third plate electrode structures 970 extending in the first direction D1 at opposite sides (i.e., opposite sidewalls), respectively, in the second direction D2 of the second plate electrode structure 945, and the second capacitors 960 disposed in the first direction D1 between the second plate electrode structure 945 and each of the third plate electrode structures 970. A plurality of unit capacitor structures UC may be disposed in the second direction D2 and may be electrically connected to each other. The unit capacitor structure UC may have a symmetrical shape in the second direction D2 with respect to the second plate electrode structure 945. For example, the second capacitors 960 and the third plate electrode structures 970 included in the unit capacitor structure UC may be symmetrical in the second direction D2 with respect to the second plate electrode structure 945 included in the unit capacitor structure UC (e.g., see FIG. 6).

FIGS. 6 and 8 show that three unit capacitor structures disposed in the second direction D2 are connected to each other. Each of the second and third plate electrode structures 945 and 970 may extend in the third direction D3, and a plurality of second capacitors 960 may be spaced apart from each other in each of the first and third directions D1 and D3 between the second and third plate electrode structures 945 and 970.

In example embodiments, the third capacitor electrode 962 (see FIG. 6) included in each of the second capacitors 960 may contact the second plate electrode structure 945 and may be electrically connected to the second plate electrode structure 945, and the fourth capacitor electrode 966 (see FIG. 6) may contact the third plate electrode structure 970 and may be electrically connected to the third plate electrode structure 970. For example, the second plate electrode structure 945 may extend in the third direction D3 on the first substrate 100 and may commonly contact (e.g., may be physically and/or electrically connected in common to) ones of the second capacitors 960.

In example embodiments, a source voltage V_{SS} may be applied to each of the second plate electrode structures 945 included in the second capacitor structure through, e.g., the fourth contact plug 618, and a drain voltage V_{DD} may be applied to each of the third plate electrode structures 970 included in the second capacitor structure through, e.g., the fifth contact plug 619. Thus, a same voltage corresponding to a difference between the source voltage V_{SS} and the drain voltage V_{DD}) may be commonly applied to the second capacitors 960 included in each of the unit capacitor structures UC, so that the second capacitors 960 may be connected in parallel. Thus, a capacitance of the second capacitor structure may be a sum of capacitances of the second capacitors 960 included in the second capacitor structure.

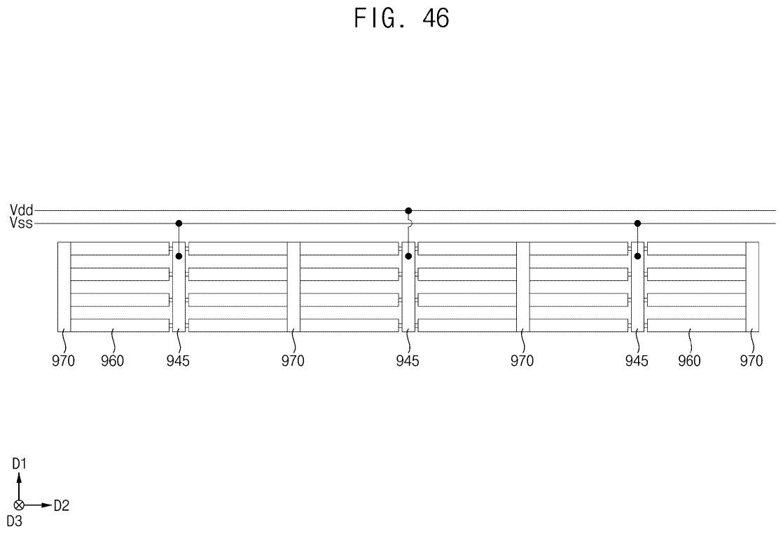

However, the inventive concepts are not limited thereto, and the second capacitor structure may include unit capacitor structures electrically connected to each other in various ways, which are discussed in greater detail below with reference to the FIGS. 46 to 52.

The semiconductor device may include the second capacitor structure at the lower portion of the peripheral circuit region, and the second capacitor structure may serve as a decoupling capacitor or a pumping capacitor to enhance electrical characteristics of the semiconductor device.

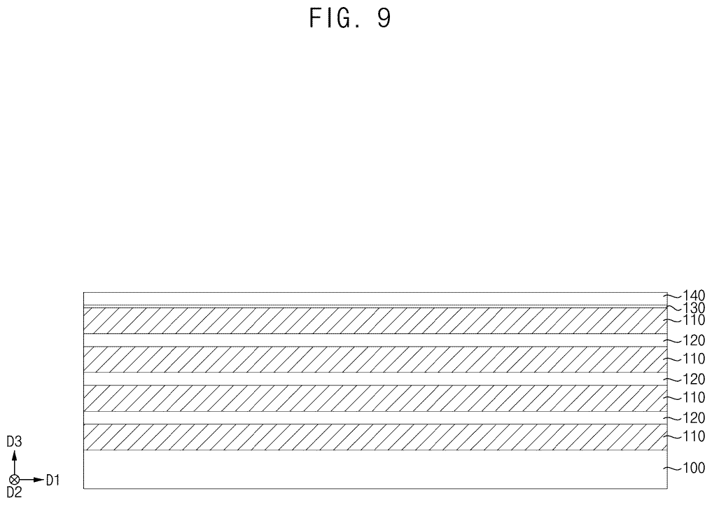

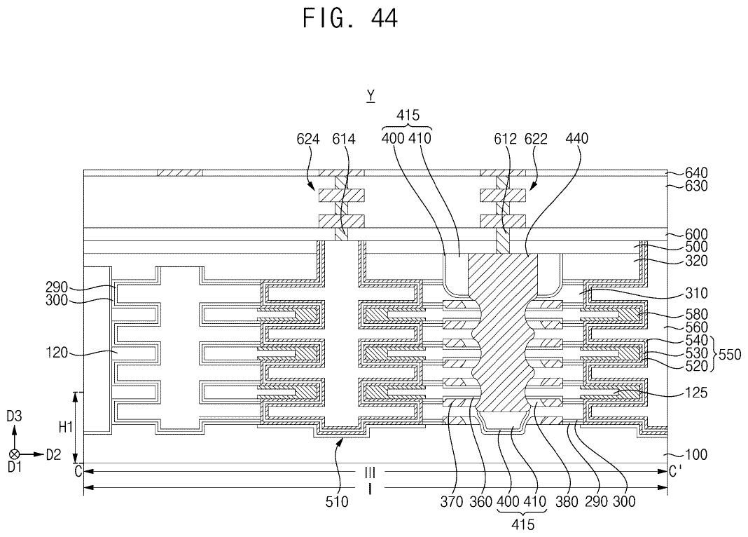

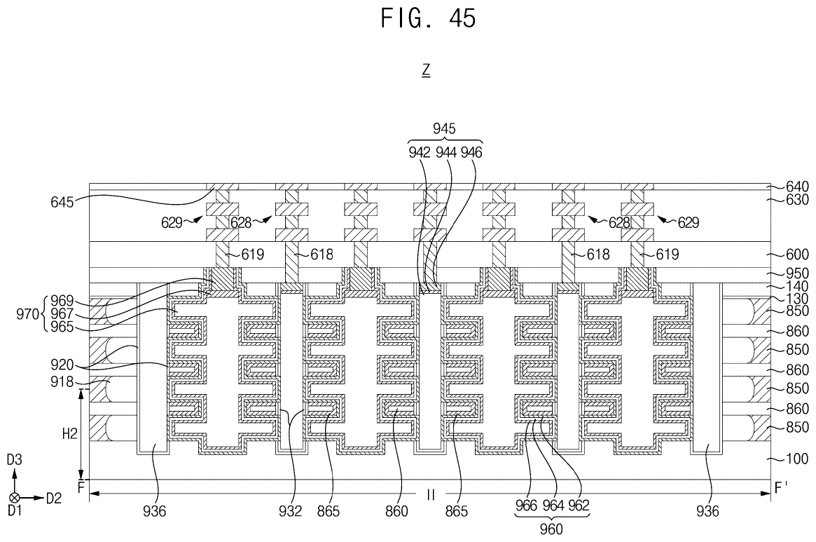

FIGS. 9 to 45 are vertical cross-sectional views and horizontal cross-sectional views illustrating a method of manufacturing a semiconductor device in accordance with example embodiments.

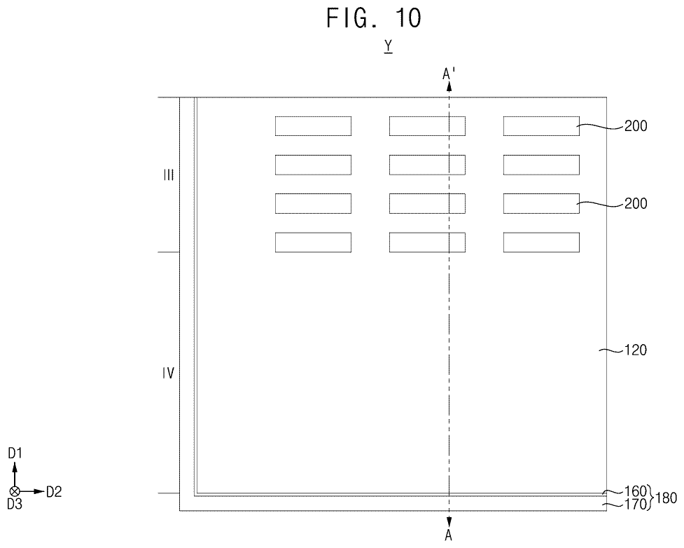

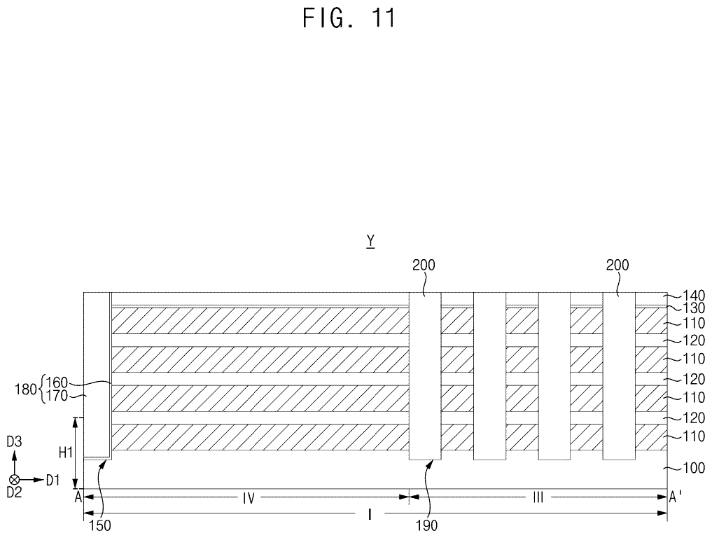

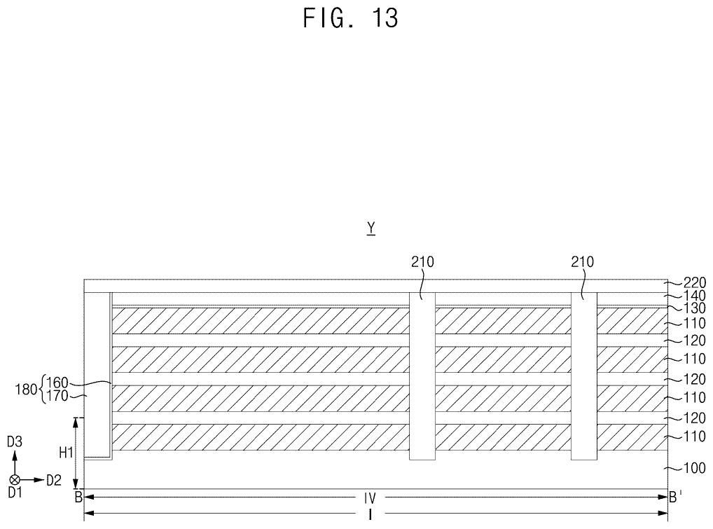

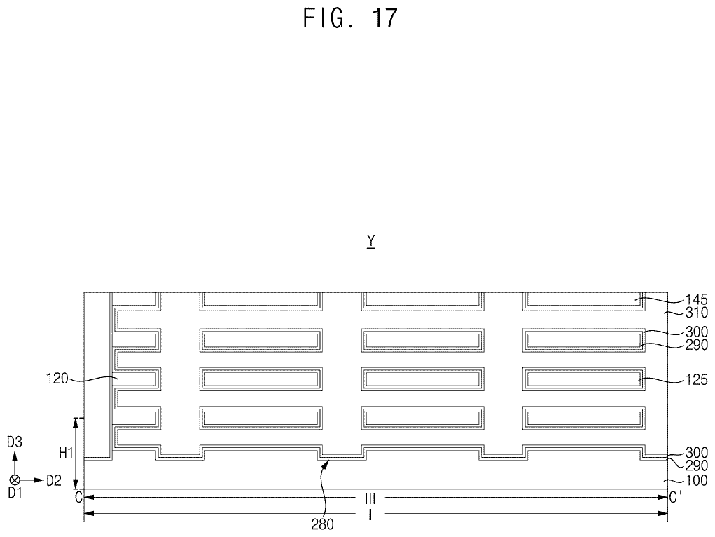

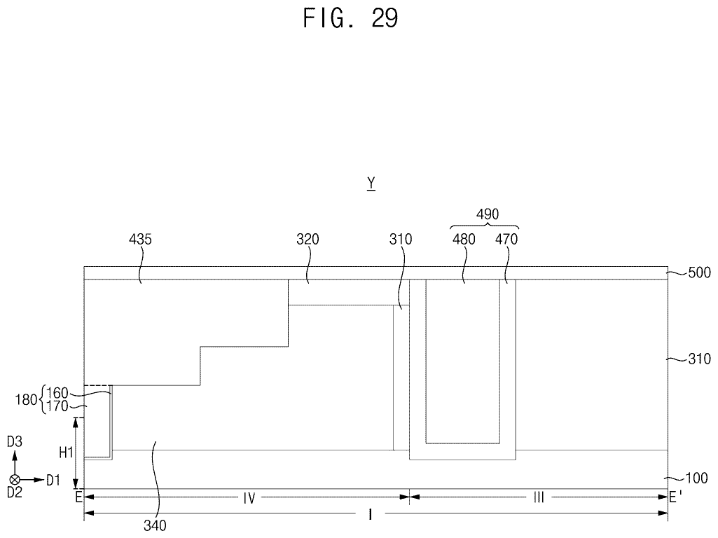

FIGS. 10 to 31 and FIGS. 43 and 44 are drawings of a first region I of a first substrate 100. Specifically, FIGS. 10, 12, 14, 16, 18, 20, 22, 24, 26, 28 and 30 are horizontal cross-sectional views at a first height H1 of corresponding vertical cross-sectional views, respectively, FIGS. 11, 25 and 43 are vertical cross-sectional views taken along lines A-A′ of corresponding horizontal cross-sectional views, respectively, FIGS. 13, 15, 19 and 23 are vertical cross-sectional views taken along lines B-B′ of corresponding horizontal cross-sectional views, respectively, FIGS. 17, 21, 27, 31 and 44 are vertical cross-sectional views taken along lines C-C′ of corresponding horizontal cross-sectional views, respectively, and FIG. 29 is a vertical cross-sectional view taken along line E-E′ of a corresponding horizontal cross-sectional view.

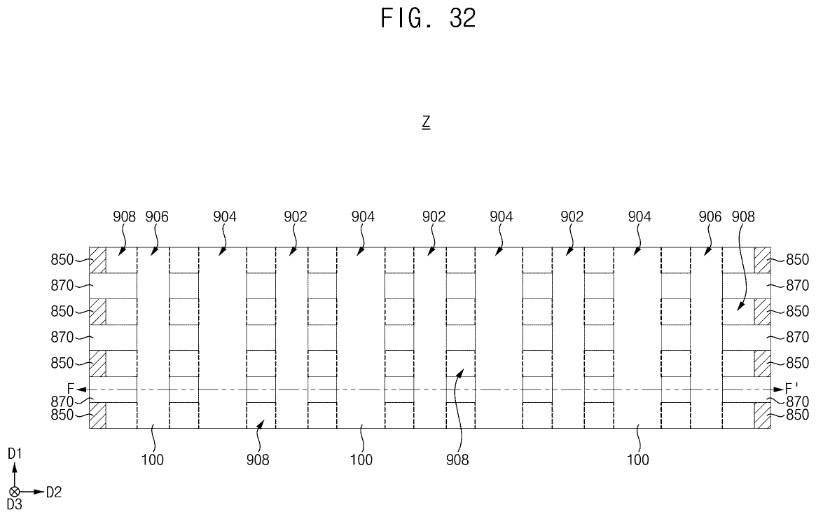

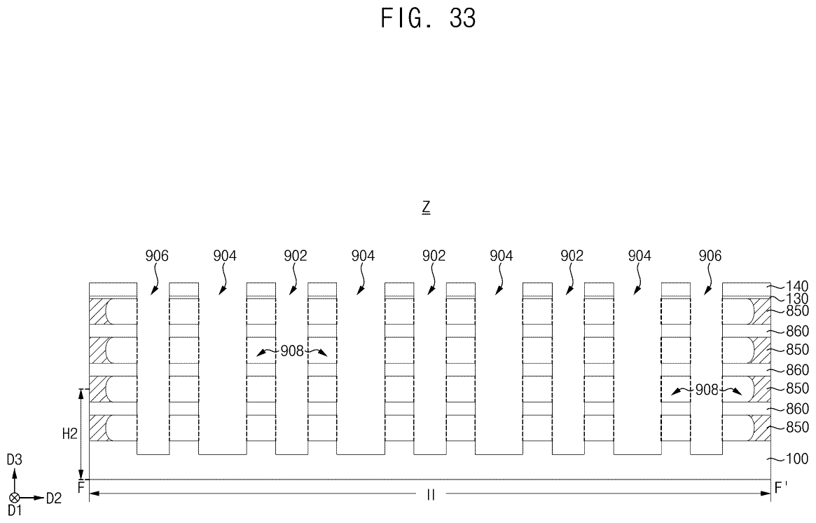

FIGS. 32 to 42 and FIG. 45 are drawings of a second region II of the first substrate 100. Specifically, FIGS. 32, 34, 36, 38 and 40 are horizontal cross-sectional views at a second height H2 of corresponding vertical cross-sectional views, respectively, and FIGS. 33, 35, 37, 39, 41, 42 and 45 are vertical cross-sectional views taken along lines F-F′ of corresponding horizontal cross-sectional views, respectively.

FIG. 9 is a vertical cross-sectional view of the first and second regions I and II of the first substrate 100.

Referring to FIG. 9, a sacrificial layer 110 and a semiconductor layer 120 may be alternately and repeatedly stacked on a first substrate 100 including first and second regions I and II (refer to FIGS. 1 and 2) to form a mold layer.

FIG. 9 shows that the sacrificial layer 110 and the semiconductor layer 120 are stacked at four levels and three levels, respectively, on the first substrate 100, but the present disclosure is not limited thereto and the sacrificial layer 110 and the semiconductor layer 120 may be stacked at more or less than four levels and three levels, respectively.

In example embodiments, the mold layer may be formed by an epitaxial growth process using an upper surface of the first substrate 100 as a seed.

In example embodiments, the semiconductor layer 120 may include, e.g., silicon, and the sacrificial layer 110 may include a material having an etching selectivity with respect to the semiconductor layer 120, e.g., silicon-germanium.

An insulating pad layer 130 and a first mask layer 140 may be sequentially stacked in the third direction D3 on the mold layer. The insulating pad layer 130 may include an oxide, e.g., silicon oxide, and the first mask layer 140 may include an insulating nitride, e.g., silicon nitride.

Referring to FIGS. 10 and 11, for example, a dry etching process may be performed on the first mask layer 140, the insulating pad layer 130 and the mold layer to form a first opening 150 extending through the first mask layer 140, the insulating pad layer 130 and the mold layer and exposing an upper surface of the first substrate 100 on the first region I of the first substrate 100, and a first division structure 180 may be formed in the first opening 150.

In example embodiments, the first division structure 180 may have a lattice shape in a plan view, and thus a plurality of memory block regions each of which may have, e.g., a rectangular shape in a plan view may be defined in each of the first and second directions D1 and D2 on the first region I of the first substrate 100. However, the inventive concepts are not limited thereto, and each of the memory block regions may have other shapes in a plan view. FIG. 10 shows a portion of the first division structure 180.

In example embodiments, each of the memory block regions may include third and fourth regions III and IV arranged in the first direction D1.

In example embodiments, the first division structure 180 may include a first division pattern 160 on a sidewall and a bottom of the first opening 150 and a second division pattern 170 in (e.g., filling) a remaining portion of the first opening 150. A sidewall and a lower surface of the second division pattern 170 may have the first division pattern 160 thereon (e.g., may be covered and/or overlapped by the first division pattern 160). The first division pattern 160 may include an insulating nitride, e.g., silicon nitride, and the second division pattern 170 may include an oxide, e.g., silicon oxide.

For example, a dry etching process may be performed on the first mask layer 140, the insulating pad layer 130 and the mold layer to form a second opening 190 extending through the first mask layer 140, the insulating pad layer 130 and the mold layer and exposing the upper surface of the first substrate 100 on the first region I of the first substrate 100, and a third division pattern 200 may be formed in the second opening 190.

In example embodiments, the third division pattern 200 may have a bar shape extending in the second direction D2 in a plan view, and a plurality of third division patterns 200 may be spaced apart from each other in each of the first and second directions D1 and D2. The third division pattern 200 may include an oxide, e.g., silicon oxide

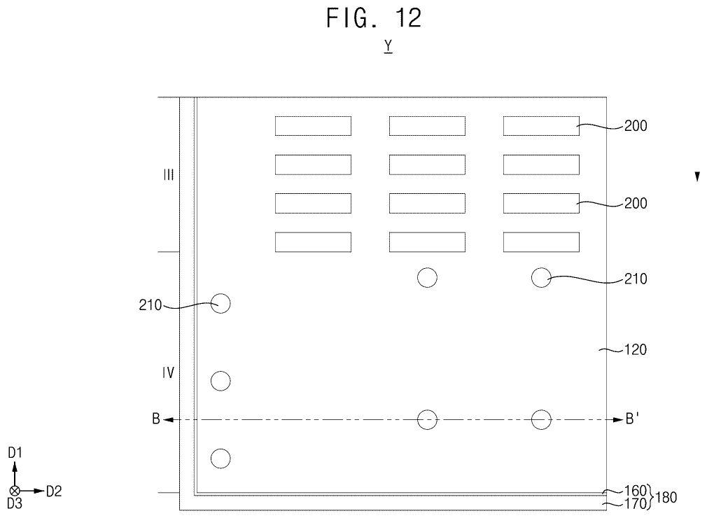

Referring to FIGS. 12 and 13, for example, a dry etching process may be performed on the first mask layer 140, the insulating pad layer 130 and the mold layer to form a third opening extending through the first mask layer 140, the insulating pad layer 130 and the mold layer and exposing the upper surface of the first substrate 100 on the first region I of the first substrate 100, and a support pattern 210 may be formed in the third opening.

In example embodiments, the support pattern 210 may have a shape of, e.g., a circle, an ellipse, a polygon, a polygon with rounded corners, etc., in a plan view, and a plurality of support patterns 210 may be spaced apart from each other in each of the first and second directions D1 and D2. The support pattern 210 may include an insulating nitride, e.g., silicon nitride.

A first insulating interlayer 220 may be formed on the first mask layer 140, the first division structure 180, the third division pattern 200 and the support pattern 210 on the first region I of the first substrate 100. The first insulating interlayer 220 may include an oxide, e.g., silicon oxide.

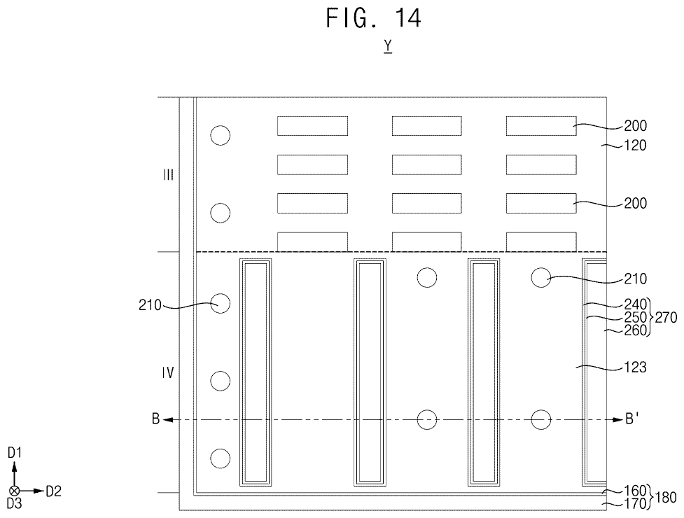

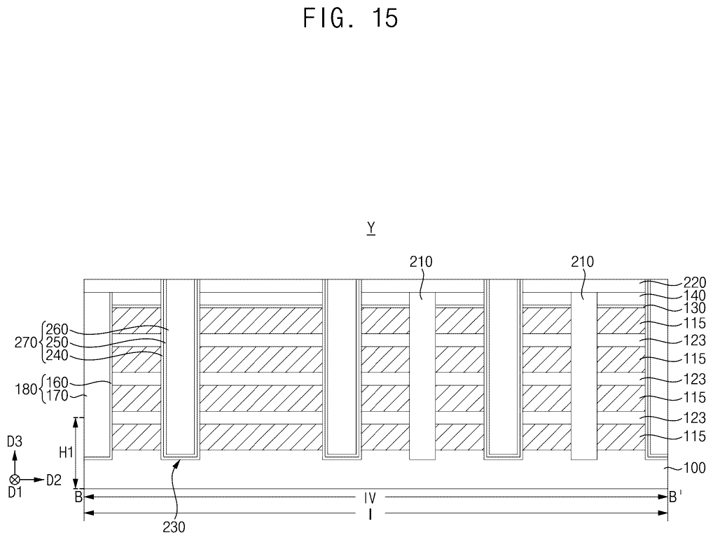

Referring to FIGS. 14 and 15, for example, a dry etching process may be performed on the first insulating interlayer 220, the first mask layer 140, the insulating pad layer 130 and the mold layer to form a fourth opening 230 extending through the first insulating interlayer 220, the first mask layer 140, the insulating pad layer 130 and the mold layer and exposing the upper surface of the first substrate 100, and a second division structure 270 may be formed in the fourth opening 230.

In example embodiments, the second division structure 270 may have a bar shape extending in the first direction D1 in a plan view, and a plurality of second division structures 270 may be spaced apart from each other in the second direction D2 in the fourth region IV. In example embodiments, each of the second division structures 270 may overlap in the first direction D1 a portion of the mold layer between ones of the third division patterns 200 neighboring in the second direction D2.

In example embodiments, the second division structure 270 may include fourth to sixth division patterns 240, 250 and 260 sequentially stacked from a sidewall and a bottom of the fourth opening 230. Each of the fourth and sixth division patterns 240 and 260 may include an oxide, e.g., silicon oxide, and the fifth division pattern 250 may include an insulating nitride, e.g., silicon nitride.

As the second division structure 270 is formed, portions of the sacrificial layer 110 and the semiconductor layer 120 included in a portion of the mold layer in the fourth region IV may be transformed into a first sacrificial pattern 115 and a first semiconductor pattern 123, respectively.

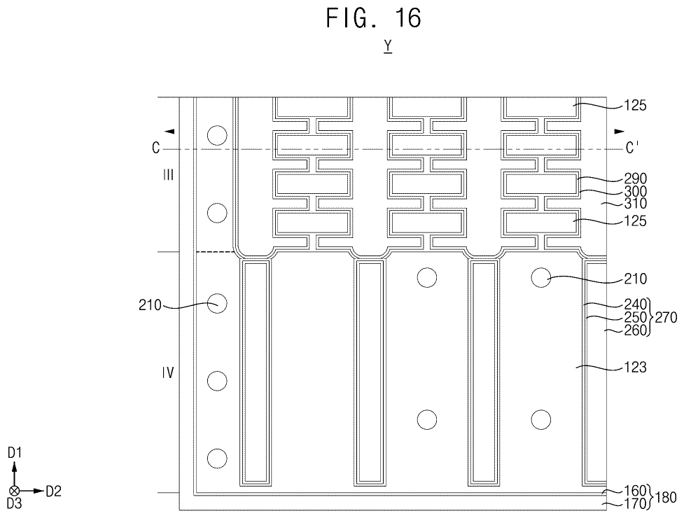

Referring to FIGS. 16 and 17, for example, a dry etching process may be performed on the first insulating interlayer 220, the first mask layer 140, the insulating pad layer 130 and the mold layer to form a fifth opening 280 extending through the first insulating interlayer 220, the first mask layer 140, the insulating pad layer 130 and the mold layer and exposing the upper surface of the first substrate 100.

In example embodiments, the fifth opening 280 may extend in the first direction D1 between ones of the third division patterns 200 neighboring in the second direction D2, and a plurality of fifth openings 280 may be spaced apart from each other in the second direction D2 in the third region III. Each of the fifth openings 280 may be aligned with a corresponding one of the second division structures 270 in the first direction D1, and may expose a sidewall of the fourth division pattern 240 at an end portion in the first direction D1 of the second division structure 270.

As the fifth openings 280 are formed, portions of the sacrificial layer 110 and the semiconductor layer 120 between ones of the third division patterns 200 neighboring in the first direction D1 and between the fifth openings 280 on the first region I of the first substrate 100 may be transformed into a second sacrificial pattern and a channel 125, respectively, and portions of the insulating pad layer 130 and the first mask layer 140 on the second sacrificial pattern may remain as an insulating pad and a first mask 145, respectively.

For example, a wet etching process may be performed through the fifth opening 280 to remove a portion of the second sacrificial pattern in the third region III, and most portion of the third division pattern 200 adjacent to the fifth opening 280 in the third region III and the insulating pad may also be removed.

Thus, a first gap may be formed between ones of the channels 125 neighboring in the third direction D3, between an uppermost one of the channels 125 and the first mask 145, and between a lowermost one of the channels 125 and the upper surface of the first substrate 100 on the third region III. Additionally, the first gap may be enlarged in the first direction D1, so that a portion of the third division pattern 200 at the same level as each of the channels 125 may remain, and other portions of the third division pattern 200 may be removed.

First and second insulating layers may be sequentially stacked on an inner wall of the first gap, a sidewall and a bottom of the fifth opening 280 and an upper surface of the first insulating interlayer 220, a seventh division layer may be formed on the second insulating layer to be in (e.g., to fill) the first gap and the fifth opening 280, and a planarization process may be performed on the seventh division layer, the first and second insulating layers, the first insulating interlayer 220 and the second division structure 270 until an upper surface of the first mask 145 is exposed. Thus, a third division structure including first and second insulating patterns 290 and 300 and a seventh division pattern 310 may be formed in the first gap and the fifth opening 280, and the first insulating interlayer 220 may be removed. The planarization process may include, e.g., a chemical mechanical polishing (CMP) process and/or an etch back process.

The first insulating pattern 290 and the seventh division pattern 310 may include an oxide, e.g., silicon oxide, and the second insulating pattern 300 may include an insulating nitride, e.g., silicon nitride. The third division pattern 200 remaining between the channels 125 may be merged with the first insulating pattern 290, and hereinafter, the merged structure may be referred to as the first insulating pattern 290. In some embodiments, the first insulating pattern 290 and a portion of the fourth division pattern 240 exposed by the fifth opening 280 may contact each other to be merged with each other.

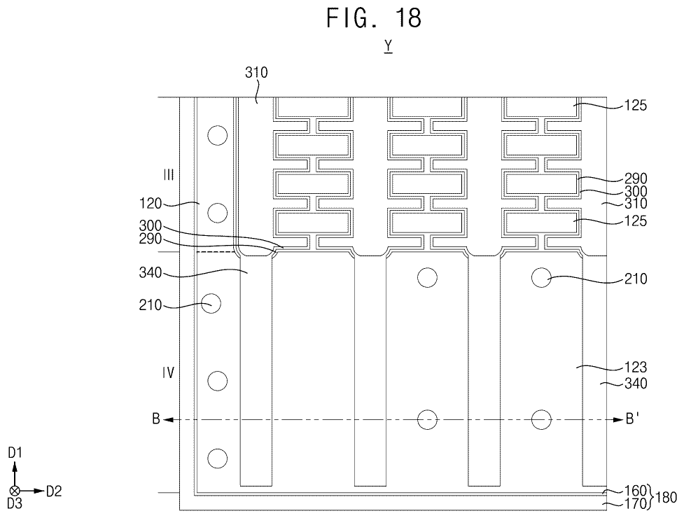

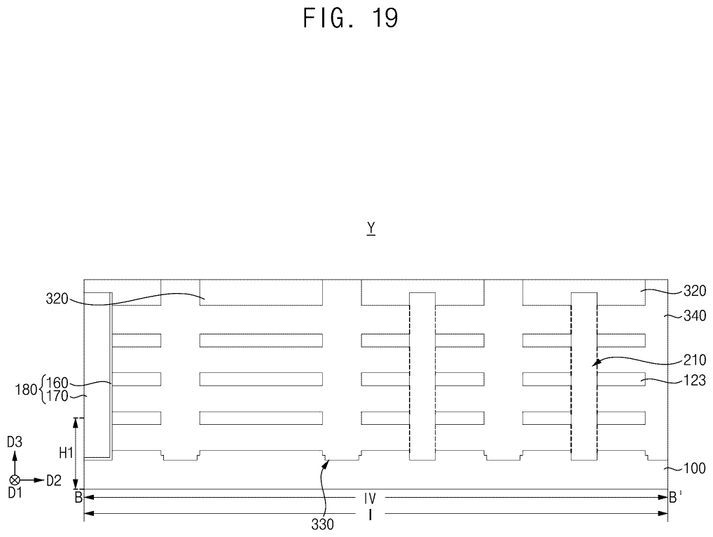

Referring to FIGS. 18 and 19, a second mask 320 may be formed on the first mask layer 140, the first mask 145, the second division structure 270 and the third division structure, and for example, a dry etching process using the second mask 320 as an etching mask may be performed to remove the second division structure 270 so that a sixth opening 330 exposing the upper surface of the first substrate 100 may be formed. A portion of the first sacrificial pattern 115 adjacent to the sixth opening 330 may be removed through the sixth opening 330, and the insulating pad layer 130 may also be removed.

Thus, a second gap may be formed between ones of the first semiconductor patterns 123 neighboring in the third direction D3, between an uppermost one of the first semiconductor patterns 123 and the first mask layer 140, and between a lowermost one of the first semiconductor patterns 123 and the first substrate 100.

The second mask 320 may include an insulating nitride, e.g., silicon nitride, and the first mask layer 140 and the first mask 145 may be merged to the second mask 320. Hereinafter, the merged structure may be referred to as the second mask 320.

An eighth division layer may be formed on the first substrate 100 and the second mask 320 to be in (e.g., to fill) the second gap and the sixth opening 330, and a planarization process may be performed on the eighth division layer until an upper surface of the second mask 320 is exposed to form an eighth division pattern 340 in the second gap and the sixth opening 330. The eighth division pattern 340 may include an insulating nitride, e.g., silicon nitride, and thus, in some embodiments, the support pattern 210 may be merged to the eighth division pattern 340.

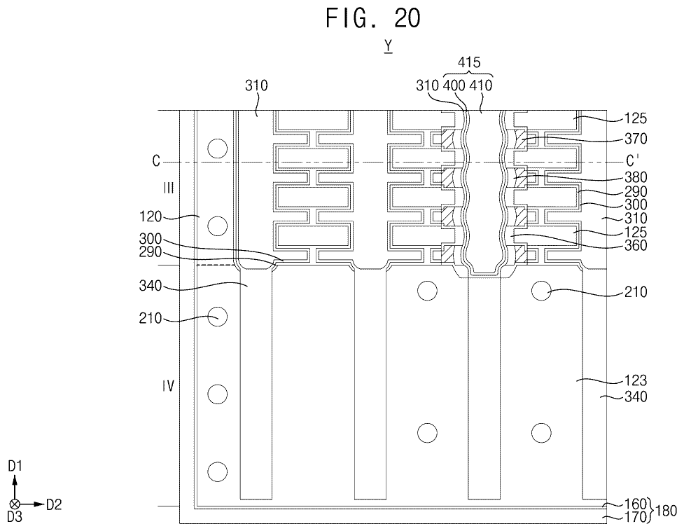

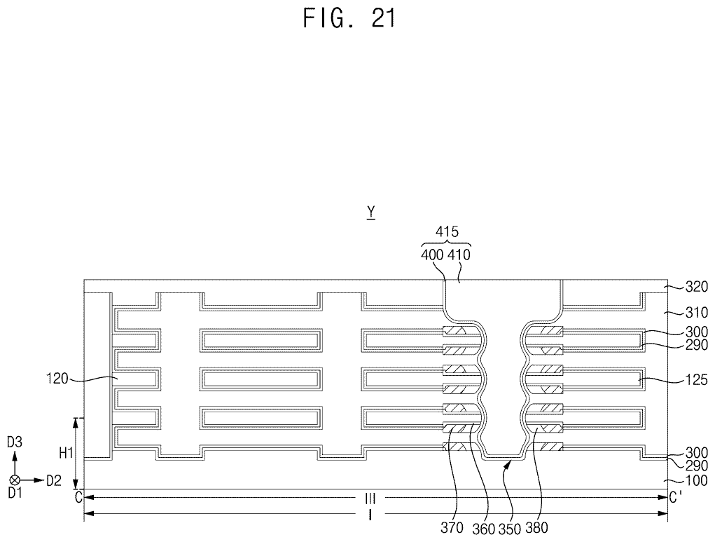

Referring to FIGS. 20 and 21, the second mask 320 and the third division structure may be partially removed by, for example, a dry etching process to form a seventh opening 350 exposing the upper surface of the first substrate 100 on the first region I of the first substrate 100.

In example embodiments, lower and upper surfaces and a sidewall of an end portion in the second direction D2 of the channel 125 may be exposed by the seventh opening 350.

For example, a thermal oxidation process may be performed to form a first gate insulating pattern 360 on (e.g., covering and/or overlapping) the lower and upper surfaces and the sidewall of the end portion of the channel 125 exposed by the seventh opening 350.

A first gate electrode layer may be formed on a sidewall and a bottom of the seventh opening 350 and the first gate insulating pattern 360, and a wet etching process or a dry etching process may be performed on the first gate electrode layer to form a first gate electrode 370 surrounding a portion of the first gate insulating pattern 360.

A gate mask layer may be formed on the sidewall and the bottom of the seventh opening 350, the first gate insulating pattern 360 and the first gate electrode 370, a wet etching process or a dry etching process may be performed on the gate mask layer to form a gate mask 380 surrounding a portion of the first gate insulating pattern 360 and contacting a sidewall in the second direction D2 of the first gate electrode 370.

The first gate electrode 370, the first gate insulating pattern 360 and the gate mask 380 may collectively form a first gate structure, and may extend in the first direction D1 to surround an end portion in the second direction D2 of each of the channels 125 in the third region III. Thus, a plurality of first gate structures may be spaced apart from each other in the third direction D3 at each of opposite sides in the second direction D2 of the seventh opening 350. Each of the first gate structures may serve as a word line of the semiconductor device.

A filling pattern may be formed to be in (e.g., to fill) a space between the first gate structures spaced apart from each other in the third direction D3, a third insulating layer and a fourth insulating layer may be sequentially stacked on a sidewall in the second direction D2 of each of the first gate structures adjacent to the seventh opening 350, a sidewall of the filling pattern and the upper surface of the first substrate 100 exposed by the seventh opening 350, a ninth division layer may be formed to be in (e.g., to fill) the seventh opening 350, and a planarization process may be performed on the ninth division layer, the third insulating layer and the fourth insulating layer until the upper surface of the second mask 320 is exposed to form a ninth division pattern 410, a third insulating pattern and a fourth insulating pattern 400, respectively.

The filling pattern, the third insulating pattern and the ninth division pattern 410 may include an oxide, e.g., silicon oxide, and the fourth insulating pattern 400 may include an insulating nitride, e.g., silicon nitride. The filling pattern and the third insulating pattern may be merged to form the seventh division pattern 310, and hereinafter, the merged structure may be referred to as the seventh division pattern 310.

The fourth insulating pattern 400 and the ninth division pattern 410 collectively form a fourth division structure 415.

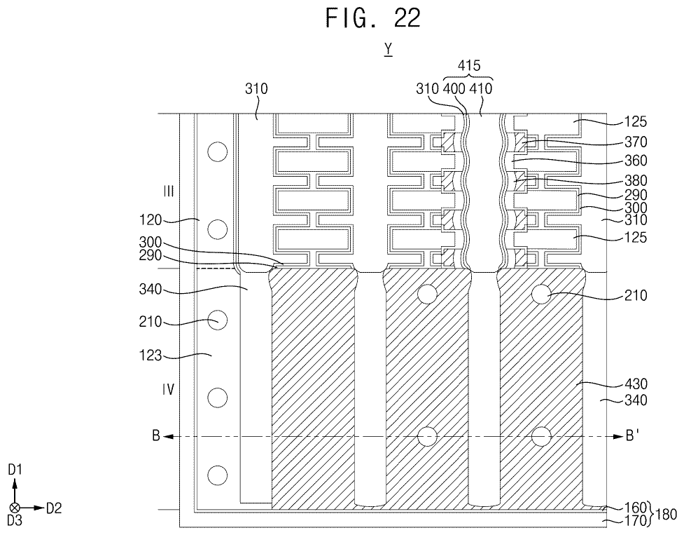

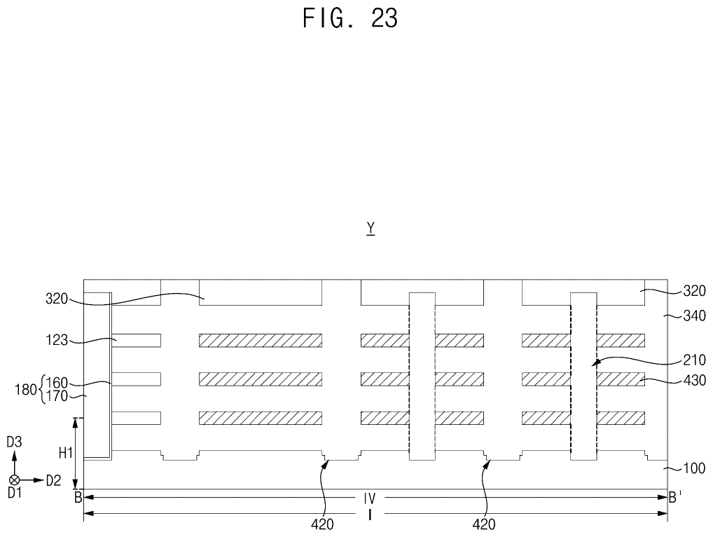

Referring to FIGS. 22 and 23, the eighth division pattern 340 may be partially removed by, for example, a dry etching process to form an eighth opening 420 exposing the upper surface of the first substrate 100, and for example, a wet etching process may be performed through the eighth opening 420 to remove the first semiconductor pattern 123 to form a third gap, a conductive pad layer may be formed in the eighth opening 420 to be in (e.g., to fill) the third gap, and for example, a wet etching process may be performed on the conductive pad layer to form a conductive pad 430 in the third gap on the first region I of the first substrate 100.

In example embodiments, the conductive pad 430 may extend in the first direction D1 in the fourth region IV, and a plurality of conductive pads 430 may be spaced apart from each other in the second direction D2. Additionally, a plurality of conductive pads 430 may be spaced apart from each other in the third direction D3.

A tenth division layer may be formed to be in (e.g., to fill) the eighth opening 420, and a planarization process may be performed on the tenth division layer until the upper surface of the second mask 320 is exposed to form a tenth division pattern in the eighth opening 420. The tenth division pattern may include an insulating nitride, e.g., silicon nitride, and may contact the eighth division pattern 340 between the conductive pads 430 spaced apart from each other in the third direction D3 to be merged to the eighth division pattern 340. Hereinafter, the eighth division pattern 340 together with the tenth division pattern merged thereto may be referred to as the eighth division pattern 340.

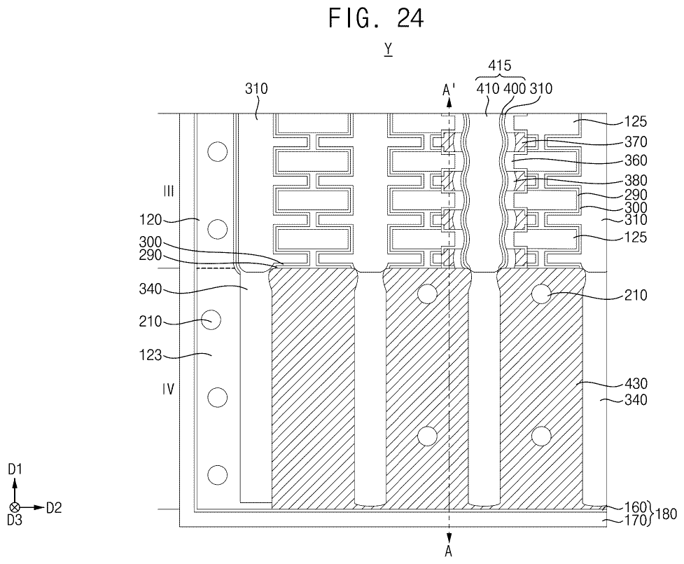

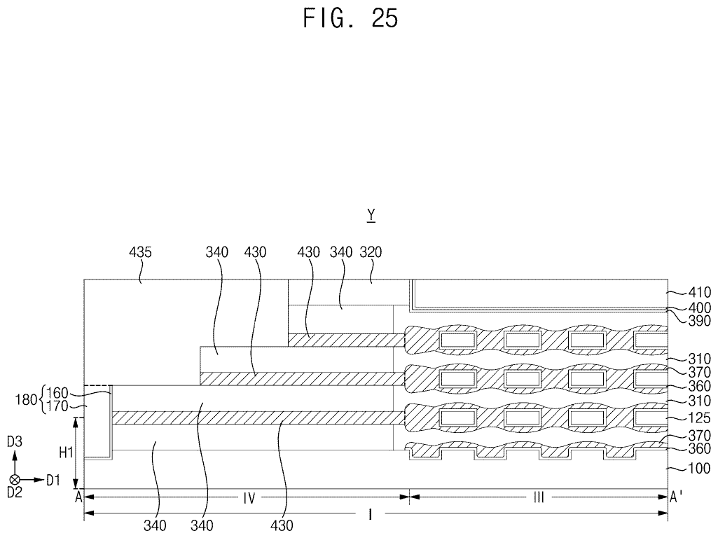

Referring to FIGS. 24 and 25, the second mask 320, the eighth division pattern 340 and the conductive pad 430 in the first region I of the first substrate 100 may be partially removed by, e.g., a dry etching process to form a ninth opening exposing an upper surface of the eighth division pattern 340.

In example embodiments, after the dry etching process, each of the conductive pads 430 and a portion of the eighth division pattern 340 thereon may collectively form a step layer extending in the first direction D1, and a stack structure including the conductive pads 430 and the eighth division patterns 340 may have a staircase structure having a length decreasing from a bottom toward a top thereof in a stepwise manner. During the dry etching process, upper portions of the first and second division patterns 160 and 170 contacting an end portion in the first direction D1 of the conductive pad 430 may also be removed.

A second insulating interlayer 435 may be formed to be in (e.g., to fill) the ninth opening. The second insulating interlayer 435 may include an oxide, e.g., silicon oxide, and may contact the second division pattern 170. In some embodiments, the second insulating interlayer 435 may be merged to the second division pattern 170.

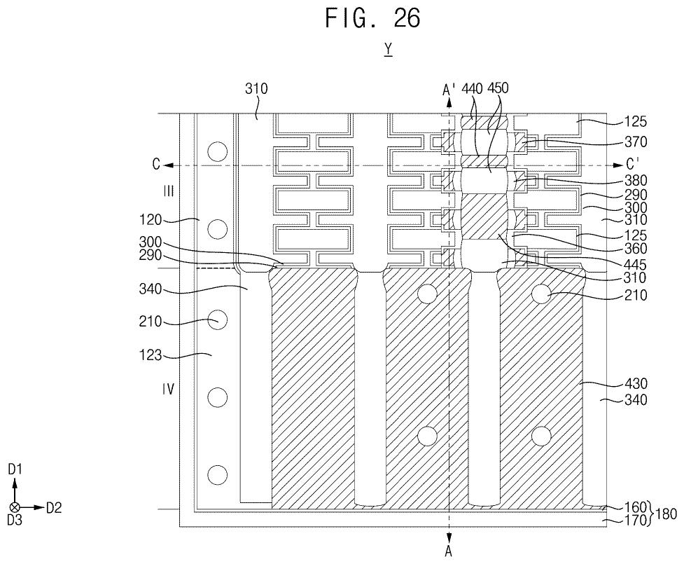

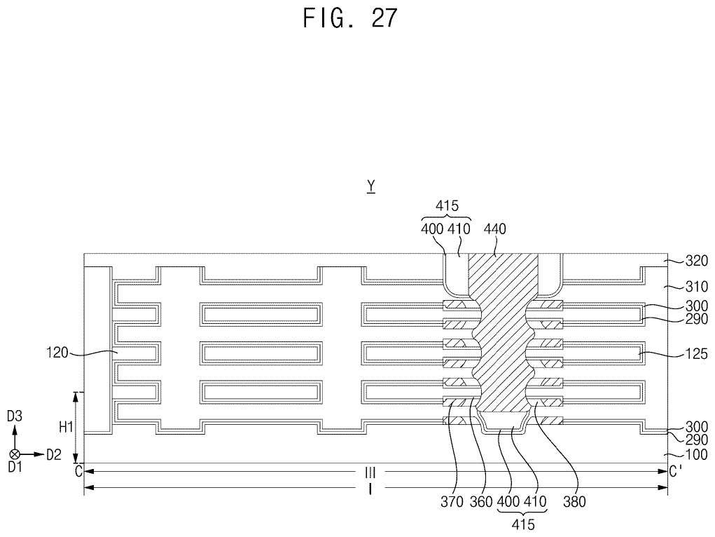

Referring to FIGS. 26 to 27, the fourth division structure 415 and the seventh division pattern 310 may be partially etched by, for example, a dry etching process on the first region I of the first substrate 100 to form a first trench, a bit line layer may be formed in the first trench, and the bit line layer may be patterned to form a bit line 440.

As the first trench is formed, end portions in the second direction D2 of the channels 125, the first gate insulating patterns 360 and the gate masks 380 that are disposed in the third direction D3 at each of opposite sides in the second direction D2 of the fourth division structure 415 may be exposed, and thus the bit line 440 extending in the third direction D3 in the first trench may contact the channels 125, the first gate insulating patterns 360 and the gate masks 380.

In example embodiments, a plurality of bit lines 440 may be spaced apart from each other in the first direction D1 in the third region III, and the plurality of bit lines 440 may contact the channels 125, respectively, disposed in the first direction D1 to be electrically connected thereto. However, one of the bit lines 440 disposed in the first direction D1 that is adjacent to the fourth region IV may be a dummy bit line 445.

In example embodiments, the bit line 440 may include polysilicon doped with n-type impurities. In other example embodiments, the bit line 440 may include, e.g., a metal, a metal nitride, a metal silicide, etc.

An eleventh division pattern 450 may be formed to be in (e.g., to fill) a space between the bit lines 440 disposed in the first direction D1. The eleventh division pattern 450 may include an oxide, e.g., silicon oxide.

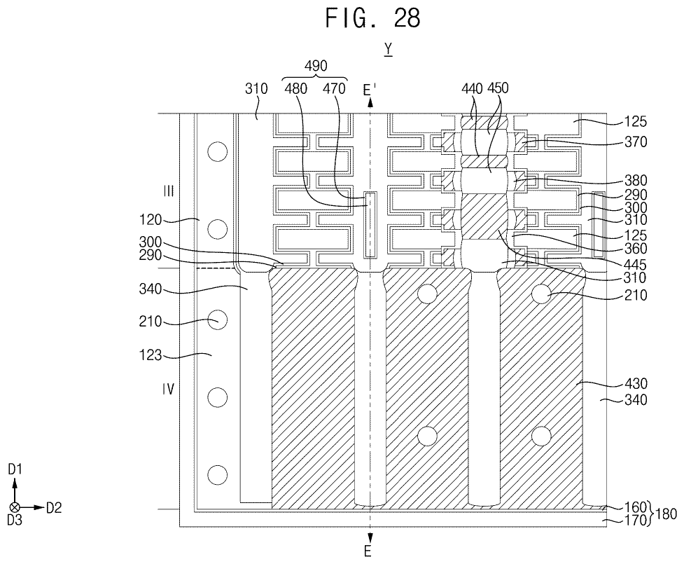

Referring to FIGS. 28 and 29, the seventh division pattern 310 may be partially removed by, for example, a dry etching process to form a tenth opening exposing the upper surface of the first substrate 100 on the first region I of the first substrate 100, and a blocking structure 490 may be formed in the tenth opening.

In example embodiments, the blocking structure 490 may be formed in a portion of the third region III adjacent to the fourth region IV, and may be formed between ones of the channels 125 neighboring in the second direction D2 at an opposite side in the second direction D2 of the bit line 440 with respect to the channel 125.

In example embodiments, the blocking structure 490 may include a first blocking pattern 470 on a sidewall and a bottom of the tenth opening and a second blocking pattern 480 in (e.g., filling) a remaining portion of the tenth opening. A sidewall and a lower surface of the second blocking pattern 480 may have the first blocking pattern 470 thereon (e.g., may be covered and/or overlapped by the first blocking pattern 470). The first blocking pattern 470 may include an insulating nitride, e.g., silicon nitride, and the second blocking pattern 480 may include an oxide, e.g., silicon oxide.

In example embodiments, the blocking structure 490 may have a shape of a polygon, e.g., a rectangle in a plan view, however, the inventive concepts are not limited thereto.

A first capping layer 500 may be formed on the blocking structure 490, the bit line 440, the dummy bit line 445, the second insulating interlayer 435, the second mask 320, the seventh division pattern 310, the fourth division structure 415 and the eleventh division pattern 450. The first capping layer 500 may include an insulating nitride, e.g., silicon nitride

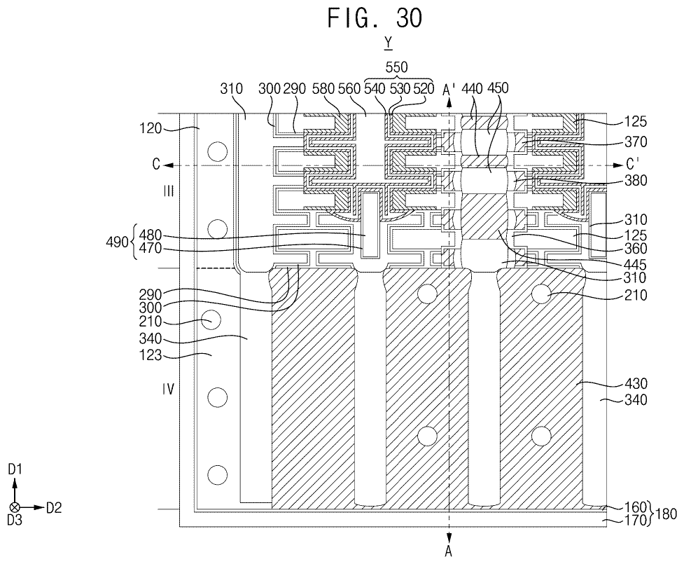

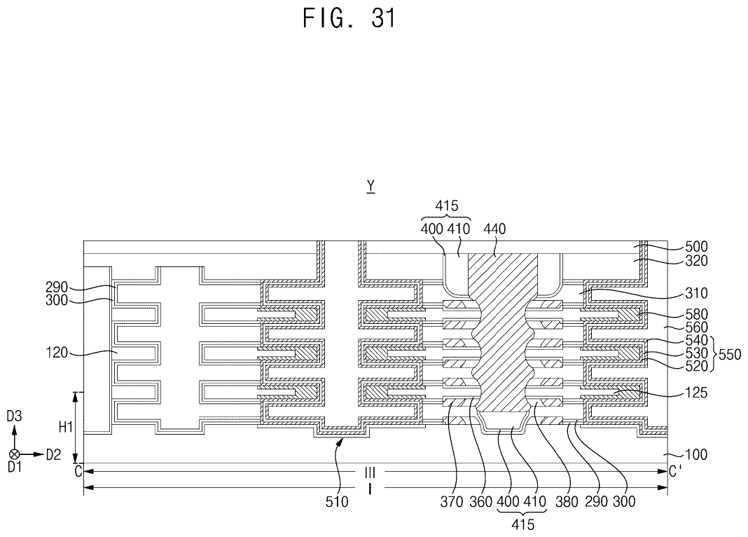

Referring to FIGS. 30 and 31, the first capping layer 500, the second mask 320 and the third division structure may be partially removed by, for example, a dry etching process to form an eleventh opening 510 exposing the upper surface of the first substrate 100 on the first region I of the first substrate 100.

In example embodiments, the eleventh opening 510 may expose a sidewall in the first direction D1 of the blocking structure 490.

For example, a wet etching process may be performed through the eleventh opening 510 to remove a portion of the seventh division pattern 310 between ones of the channels 125 that are neighboring in the third direction D3 and adjacent to the eleventh opening 510 to form a fourth gap. During the wet etching process, portions of the first and second insulating patterns 290 and 300 on lower and upper surfaces and a sidewall of a portion of the channel 125 may also be removed to expose the portion of the channel 125.

A first capacitor electrode layer, a first dielectric layer and a second capacitor electrode layer may be sequentially stacked on an inner wall of the fourth gap, an inner wall of the eleventh opening 510 and an upper surface of the first capping layer 500, a first plate electrode layer may be formed on the second capacitor electrode layer to be in (e.g., to fill) the fourth gap and the eleventh opening 510, and a planarization process may be performed on the first plate electrode layer, the first and second capacitor electrode layers and the first dielectric layer until the upper surface of the first capping layer 500 is exposed to form a first plate electrode 560, first and second capacitor electrodes 520 and 540 and a first dielectric pattern 530, respectively, in the fourth gap and the eleventh opening 510.

When the first capacitor electrode layer is formed, a first metal silicide pattern 580 may be formed at a portion of the channel 125 contacting the first capacitor electrode layer.

The first and second capacitor electrodes 520 and 540 and the first dielectric pattern 530 may collectively form a first capacitor 550, and the first capacitor 550 together with the first plate electrode 560 may collectively form a first capacitor structure.

Referring to FIGS. 32 and 33, for example, a dry etching process may be performed on the first mask layer 140, the insulating pad layer 130 and the mold layer to form a twelfth opening extending through the first mask layer 140, the insulating pad layer 130 and the mold layer and exposing the upper surface of the first substrate 100, and a twelfth division layer may be formed in the twelfth opening on the second region II of the first substrate 100.

In example embodiments, the twelfth division layer may extend in the second direction D2 on the second region II of the first substrate 100, and a plurality of twelfth division layers may be spaced apart from each other in the first direction D1. The twelfth division layer may include an insulating nitride, e.g., silicon nitride.

For example, a dry etching process may be performed on the first mask layer 140, the insulating pad layer 130, the mold layer and the twelfth division layer to form thirteenth to fifteenth openings 902, 904 and 906 extending through on the first mask layer 140, the insulating pad layer 130, the mold layer and the twelfth division layer and exposing the upper surface of the first substrate 100 on the second region II of the first substrate 100.

In example embodiments, each of the thirteenth to fifteenth openings 902, 904 and 906 may extend in the first direction D1 on the second region II of the first substrate 100, and the thirteenth to fifteenth openings 902, 904 and 906 may be spaced apart from each other in the second direction D2. In example embodiments, the fourteenth and thirteenth openings 904 and 902 may be alternately and repeatedly disposed and spaced apart from each other in the second direction D2 between ones of the fifteenth openings 906 spaced apart from each other in the second direction D2. As the thirteenth to fifteenth openings 902, 904 and 906 are formed, the twelfth division layer extending in the second direction D2 may be separated into a plurality of twelfth division patterns 870 spaced apart from each other in the second direction D2.

As the twelfth division layer and the thirteenth to fifteenth openings 902, 904 and 906 are formed, the sacrificial layer 110 and the semiconductor layer 120 on the second region II of the first substrate 100 may be separated into third sacrificial patterns 850 and second semiconductor patterns 860, respectively. A plurality of third sacrificial patterns 850 may be spaced apart from each other in each of the first and second directions D1 and D2, and a plurality of semiconductor patterns 860 may be spaced apart from each other in each of the first and second directions D1 and D2.

For example, a wet etching process may be performed to remove a portion of the third sacrificial pattern 850 adjacent to each of the thirteenth to fifteenth openings 902, 904 and 906 in the second direction D2 to form a fifth gap 908. Thus, the third sacrificial patterns 850 between the thirteenth to fifteenth openings 902, 904 and 906 may be removed, and a portion of each of the third sacrificial patterns 850 at a side in the second direction D2 of the fifteenth opening 906 may remain.

The fifth gap 908 may be formed between ones of the second semiconductor patterns 860 neighboring in the third direction D3, between an uppermost one of the second semiconductor patterns 860 and a lower surface of the insulating pad layer 130, and a lowermost one of the second semiconductor patterns 860 and the upper surface of the first substrate 100. Thus, a plurality of fifth gaps 908 may be spaced apart from each other in each of the first and second directions D1 and D2.

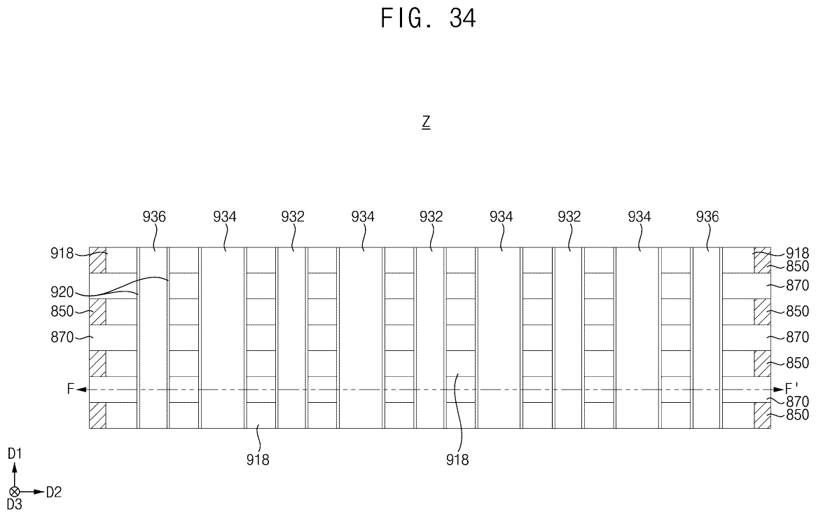

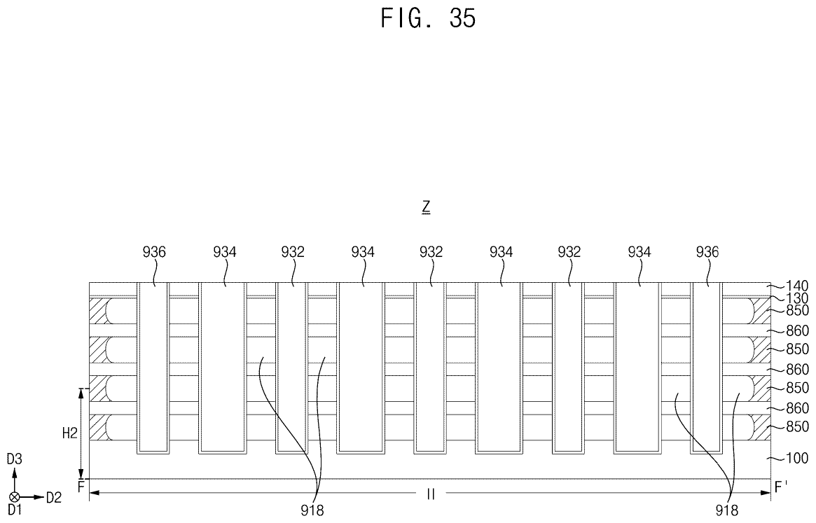

Referring to FIGS. 34 and 35, a fifth insulating layer may be formed in the thirteenth to fifteenth openings 902, 904 and 906 and the fifth gap 908, the fifth insulating layer in the thirteenth to fifteenth openings 902, 904 and 906 may be removed by, for example, a wet etching process, and thus a fifth insulating pattern 918 may be formed in the fifth gap 908.

A plurality of fifth insulating patterns 918 may be spaced apart from each other in each of the first and second directions D1 and D2, and may include an oxide, e.g., silicon oxide.

A liner layer may be formed on inner walls of the thirteenth to fifteenth openings 902, 904 and 906 and an upper surface of the first mask layer 140, a thirteenth division layer may be formed on the liner layer to be in (e.g., to fill) the thirteenth to fifteenth openings 902, 904 and 906, and a planarization process may be performed on the thirteenth division layer and the liner layer until the upper surface of the first mask layer 140 is exposed to form thirteenth to fifteenth division patterns 932, 934 and 936 and a liner 920, respectively.

The thirteenth to fifteenth division patterns 932, 934 and 936 may be formed in the thirteenth to fifteenth division openings 902, 904 and 906, respectively. Each of the thirteenth to fifteenth division patterns 932, 934 and 936 may extend in the first direction D1 on the second region II of the first substrate 100, and a sidewall and a lower surface of each of the thirteenth to fifteenth division patterns 932, 934 and 936 may have the liner 920 thereon (e.g., may be covered and/or overlapped by the liner 920).

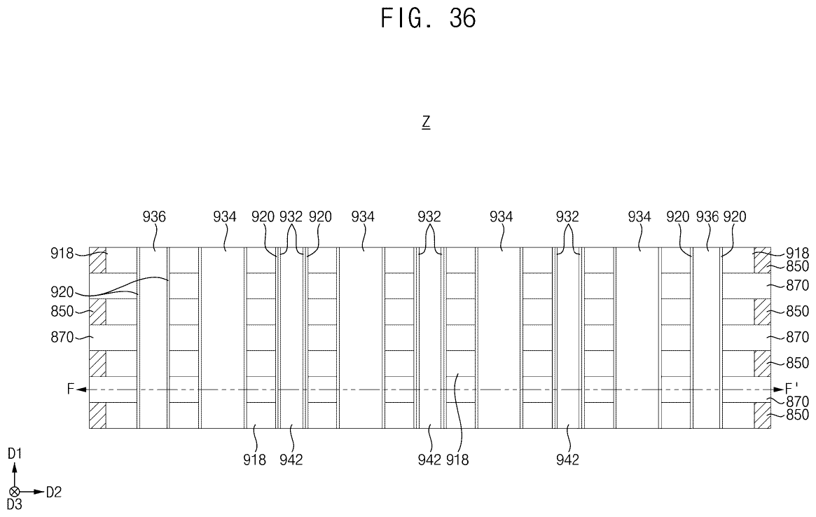

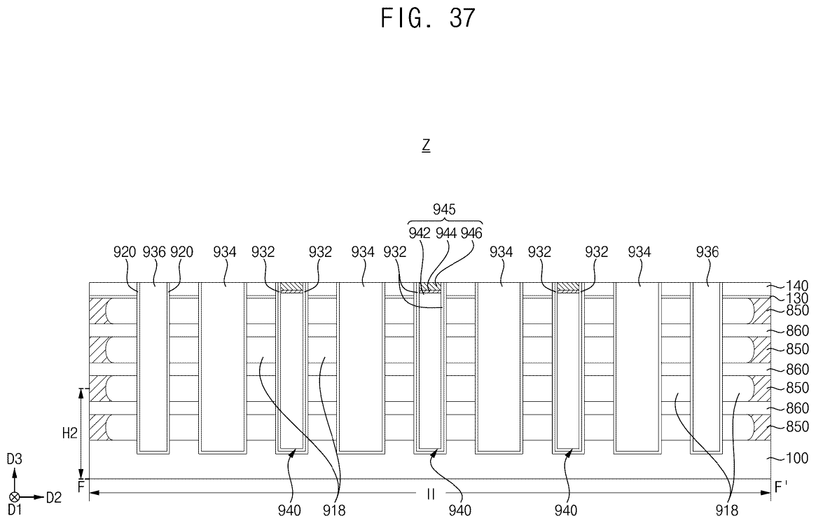

Referring to FIGS. 36 and 37, the thirteenth division pattern 932 may be partially removed by, for example, a dry etching process to form a second trench 940 on the second region II of the first substrate 100, and a second plate electrode structure 945 may be formed in the second trench 940.

In example embodiments, the second plate electrode structure 945 may extend in the first direction D1 on the second region II of the first substrate 100, and a sidewall and a lower surface of the second plate electrode structure 945 may have the thirteenth division pattern 932 thereon (e.g., may be covered and/or overlapped by the thirteenth division pattern 932). In example embodiments, the second plate electrode structure 945 may include first to third conductive patterns 942, 944 and 946 sequentially stacked in the third direction D3.

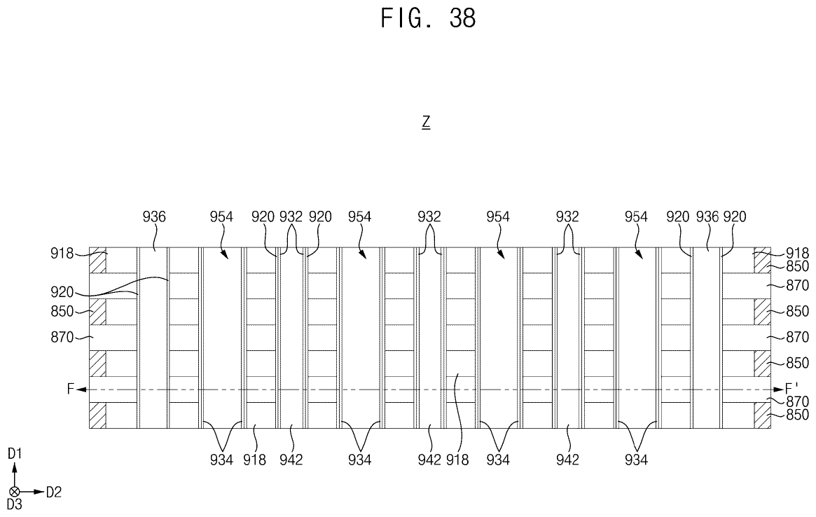

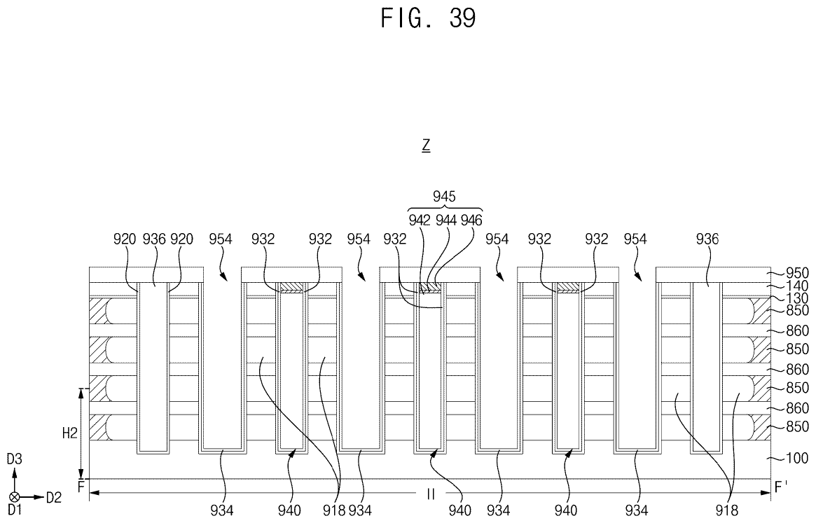

Referring to FIGS. 38 and 39, a second capping layer 950 may be formed on the first mask layer 140, the thirteenth to fifteenth division patterns 932, 934 and 936, the liner 920 and the second plate electrode structure 945 on the second region II of the first substrate 100, and the second capping layer 950 and the fourteenth division pattern 934 may be partially removed by, for example, a dry etching process, to form a third trench 954.

The second capping layer 950 may include an insulating nitride, e.g., silicon nitride, and in some embodiments, may be merged to the first mask layer 140.

In example embodiments, the third trench 954 may extend in the first direction D1 on the second region II of the first substrate 100.

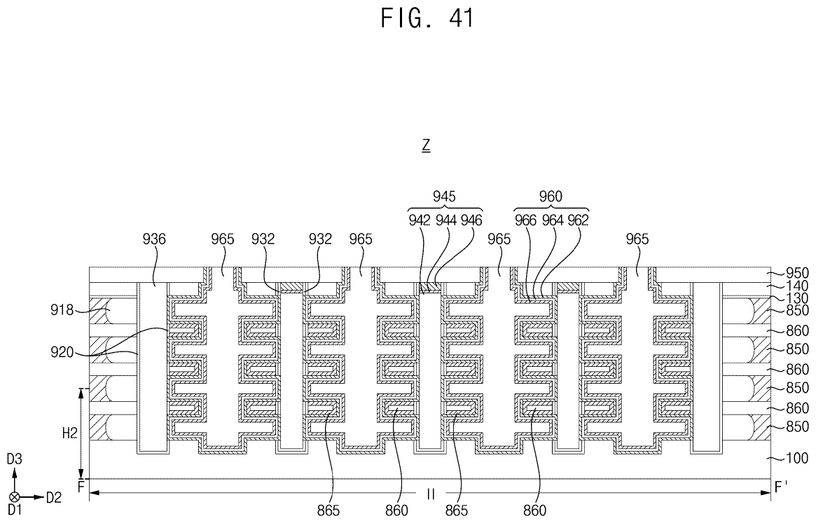

Referring to FIGS. 40 and 41, the fourteenth division pattern 934, the liner 920 and the fifth insulating pattern 918 adjacent to the third trench 954 may be partially removed by, for example, a wet etching process, to form a sixth gap on the second region II of the first substrate 100.

During the wet etching process, a portion of the insulating pad layer 130 adjacent to the third trench 954 and portions of the thirteenth division pattern 934 and the liner 920 on the sidewall of the second plate electrode structure 945 may also be partially removed.

A third capacitor electrode layer, a second dielectric layer and a fourth capacitor electrode layer may be sequentially stacked on an inner wall of the sixth gap, a sidewall of the first mask layer 140, a sidewall and an upper surface of the second capping layer 950, a surface of the second semiconductor pattern 860, the upper surface of the first substrate 100 and a sidewall of the fifteenth division pattern 936, a fourth conductive layer may be formed on the fourth capacitor electrode layer to be in (e.g., to fill) the third trench 954, and a planarization process may be performed on the fourth conductive layer, the fourth capacitor electrode layer, the second dielectric layer and the third capacitor electrode layer until the upper surface of the second capping layer 950 is exposed.

Thus, a fourth conductive pattern 965 may be formed in the third trench 954, and a fourth capacitor electrode 966, a second dielectric pattern 964 and a third capacitor electrode 962 may be sequentially stacked on a sidewall and a lower surface of the fourth conductive pattern 965. The third and fourth capacitor electrodes 962 and 966 and the second dielectric pattern 964 may collectively form a second capacitor 960.

A second metal silicide pattern 865 may be formed on a portion of the second semiconductor pattern 860 contacting the third capacitor electrode 962.

In example embodiments, the fourth conductive pattern 965 may include a second vertical extension portion extending in the direction D3 and a second horizontal extension portion extending in the second direction D2 from each of opposite sidewalls of the second vertical extension portion on the second region II of the first substrate 100. A plurality of second horizontal extension portions of the fourth conductive pattern 965 may be spaced apart from each other in the third direction D3 from each of the opposite sidewalls of the second vertical extension portion of the fourth conductive pattern 965. Each of the second capacitor 960 and the fourth conductive pattern 965 may also extend in the first direction D1.

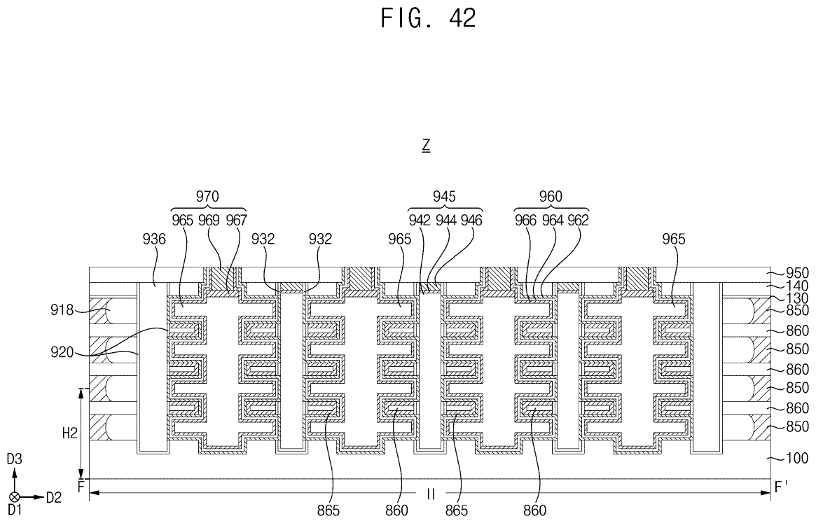

Referring to FIG. 42, an upper portion of the fourth conductive pattern 965 may be removed to form a fourth trench, and fifth and sixth conductive patterns 967 and 969 may be formed in the fourth trench.

The fourth to sixth conductive patterns 965, 967 and 969 sequentially stacked in the third direction D3 may collectively form a third plate electrode structure 970.

The second capacitor 960 and the second and third plate electrode structures 945 and 970 may collectively form a second capacitor structure.

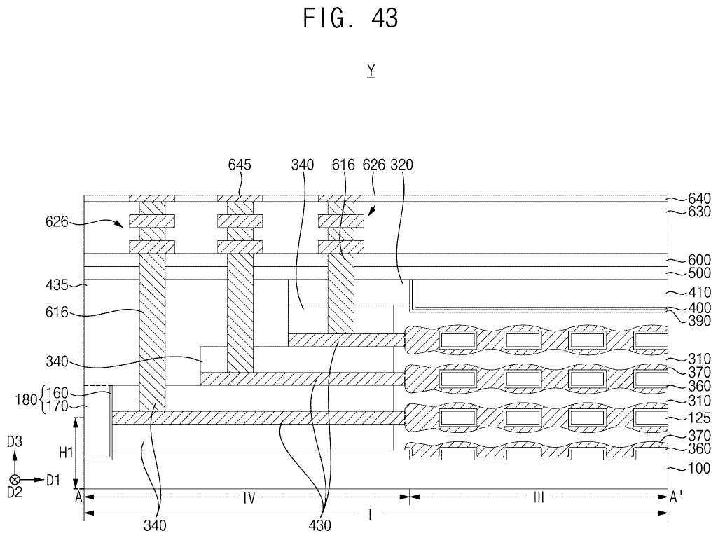

Referring to FIGS. 43 to 45, a third insulating interlayer 600 may be formed on the first and second capping layers 500 and 950 and the first and second capacitor structures on the first and second regions I and II of the first substrate 100.

A first contact plug 612 may be formed through the third insulating interlayer 600 and the first capping layer 500 to contact an upper surface of the bit line 440, a second contact plug 614 may be formed through the third insulating interlayer 600 to contact an upper surface of the first plate electrode 560, and a third contact plug 616 may be formed through the first capping layer 500, the second mask 320 and the eighth division pattern 340 or the third insulating interlayer 600, the first capping layer 500 and the second insulating interlayer 435 to contact an upper surface of the conductive pad 430 on the first region I of the first substrate 100.

A fourth contact plug 618 may be formed through the third insulating interlayer 600 and the second capping layer 950 to contact an upper surface of the second plate electrode structure 945, and a fifth contact plug 619 may be formed through the third insulating interlayer 600 to contact an upper surface of the third plate electrode structure 970 on the second region II of the first substrate 100.

First to fifth wiring structures 622, 624, 626, 628 and 629 may be formed on the third insulating interlayer 600 and the first to fifth contact plugs 612, 614, 616, 618 and 619, a fourth insulating interlayer 630 may be formed to be on (e.g., to cover and/or overlap) the first to fifth wiring structures 622, 624, 626, 628 and 629, and a first bonding layer 640 including a first bonding pad 645 may be formed on the fourth insulating interlayer 630.

Referring back to FIGS. 1 to 8, transistors may be formed on first and second regions I and II, respectively, of a second substrate 700.

Each of the transistors may include a second gate structure 730 including a second gate insulating pattern 710 and a second gate electrode 720, and impurity regions 705 at respective portions of the second substrate 700 adjacent to the second gate structure 730.

A fifth insulating interlayer 740 may be formed to be on (e.g., to cover and/or overlap) the transistors, and a sixth contact plug 750 may be formed through the fifth insulating interlayer 740 to contact each of the impurity regions 705.

Sixth and seventh wiring structures 800 and 810 may be formed on the fifth insulating interlayer 740, a sixth insulating interlayer 820 may be formed on the fifth insulating interlayer 740 to be on (e.g., to cover and/or overlap) the sixth and seventh wiring structures 800 and 810, and a second bonding layer 830 including a second bonding pad 835 may be formed on the sixth insulating interlayer 820.

The second substrate 700 may be flipped, and the second bonding layer 830 may contact the first bonding layer 640 so that the first and second substrates 100 and 700 may be bonded to each other. The first and second bonding pads 645 and 835 may contact each other.

The fabrication of the semiconductor device may be completed by the above processes.

FIGS. 46 to 52 are schematic diagrams illustrating electrical connections of second capacitor structures included in the semiconductor device in accordance with example embodiments, which may be similar to FIG. 8. For ease of description, the following description will mainly focus on differences from the description above with reference to FIG. 8.

Referring to FIG. 46, each of the third plate electrode structures 970 included in the second capacitor structure may be in a floating state (e.g., an electrically floating state), and a source voltage V_{SS} may be applied to some of the second plate electrode structures 945 included in the second capacitor structure, for example, an odd-numbered one (e.g., a first one) of the second plate electrode structures 945, and a drain voltage V_{DD} may be applied to others of the second plate electrode structures 945 included in the second capacitor structure, for example, an even-numbered one (e.g., a second one) of the second plate electrode structures 945.

Thus, a first one of the second capacitors 960 connected to the odd-numbered one of the second plate electrode structures 945 and a second one of the second capacitors 960 connected to the even-numbered one of the second plate electrode structures 945 may be electrically connected to each other through the third plate electrode structure 970 therebetween, and a voltage corresponding to a difference between the source voltage V_{SS} and the drain voltage V_{DD} may be applied to the first and second ones of the second capacitors 960.

Thus, a capacitance of the second capacitor structure of FIG. 46 may be half of a capacitance of the second capacitor structure of FIG. 8.

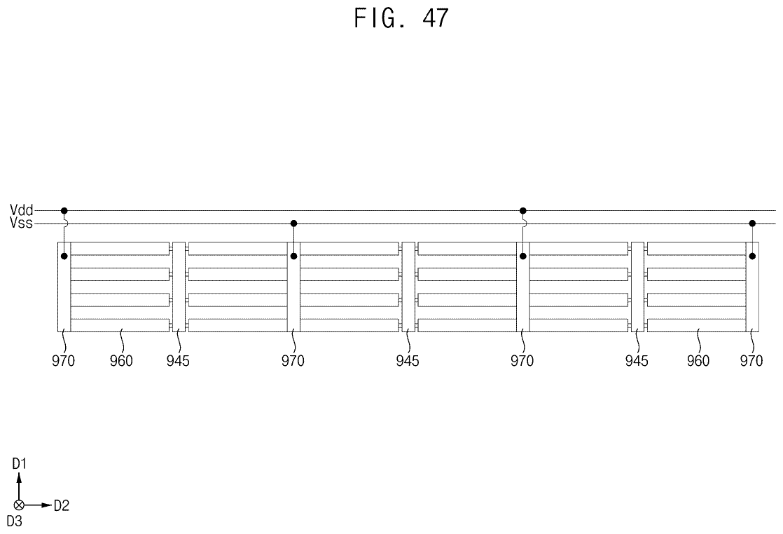

Referring to FIG. 47, each of the second plate electrode structures 945 included in the second capacitor structure may be in a floating state (e.g., an electrically floating state), and a source voltage V_{SS} may be applied to some of the third plate electrode structures 970 included in the second capacitor structure, for example, an even-numbered one (e.g., a second one) of the third plate electrode structures 970, and a drain voltage V_{DD} may be applied to others of the third plate electrode structures 970 included in the second capacitor structure, for example, an odd-numbered one (e.g., a first one) of the third plate electrode structures 970.

Thus, a first one of the second capacitors 960 connected to the even-numbered one of the third plate electrode structures 970 and a second one of the second capacitors 960 connected to the odd-numbered one of the third plate electrode structures 970 may be electrically connected to each other through the second plate electrode structure 945 therebetween, and a voltage corresponding to a difference between the source voltage V_{SS} and the drain voltage V_{DD} may be applied to the first and second ones of the second capacitors 960.

Thus, a capacitance of the second capacitor structure may be half of the capacitance of the second capacitor structure of FIG. 8.

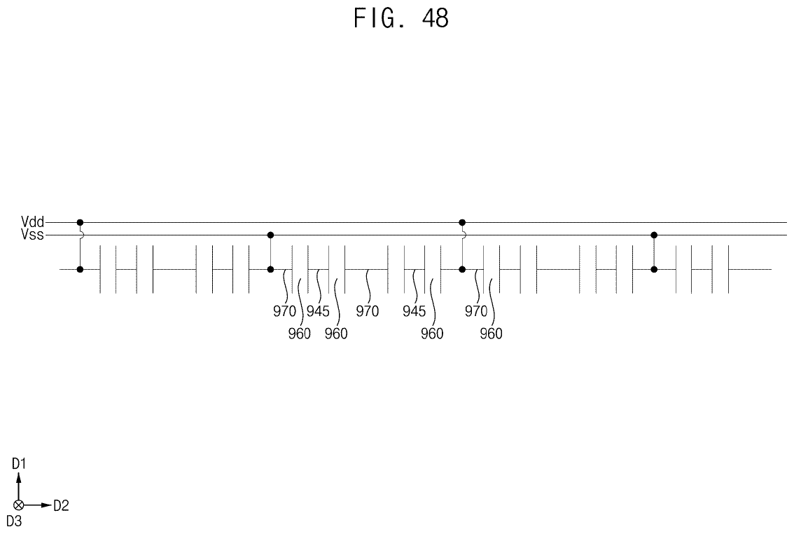

Referring to FIG. 48, each of the second plate electrode structures 945 included in the second capacitor structure and some of the third plate electrode structures 970 included in the second capacitor structure, for example, an even-numbered one (e.g., a second one) of the third plate electrode structures 970 may be in a floating state (e.g., an electrically floating state). A source voltage V_{SS} may be applied to others of the third plate electrode structures 970 included in the second capacitor structure, for example, a (4n−1)-th (n is a natural number) one of the third plate electrode structures 970, and a drain voltage V_{DD} may be applied to still others of the third plate electrode structures 970 included in the second capacitor structure, for example, a (4n−3)-th (n is a natural number) one of the third plate electrode structures 970.

Thus, four second capacitors 960 between the (4n−1)-th (n is a natural number) one of the third plate electrode structures 970 and (4n−3)-th (n is a natural number) one of the third plate electrode structures 970 may be electrically connected to each other through two second plate electrode structures 945 and one third plate electrode structure 970 therebetween, and a voltage corresponding to a difference between the source voltage V_{SS} and the drain voltage V_{DD} may be applied to the four second capacitors 960.

Thus, a capacitance of the second capacitor structure may have a quarter of the capacitance of the second capacitor structure of FIG. 8.

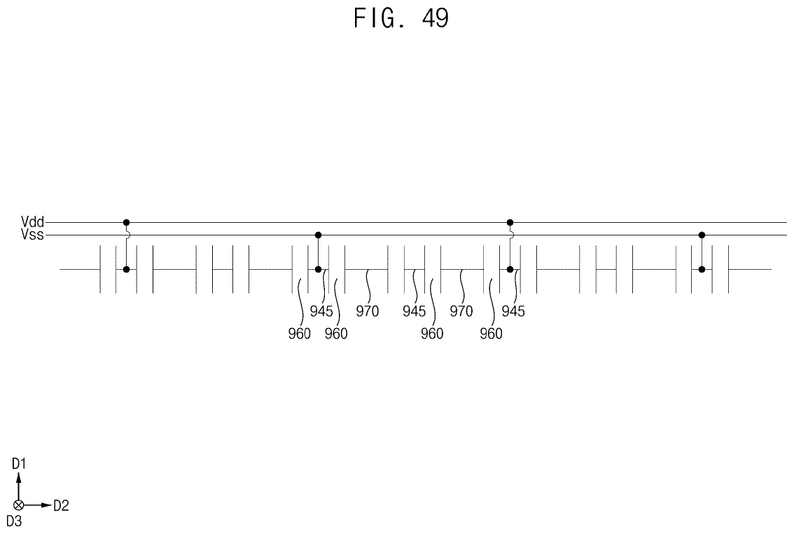

Referring to FIG. 49, each of the third plate electrode structures 970 included in the second capacitor structure and some of the second plate electrode structures 945 included in the second capacitor structure, for example, an even-numbered one (e.g., a second one) of the second plate electrode structures 945 may be in a floating state (e.g., an electrically floating state). A source voltage V_{SS} may be applied to others of the second plate electrode structures 945 included in the second capacitor structure, for example, a (4n−1)-th (n is a natural number) one of the second plate electrode structures 945, and a drain voltage V_{DD} may be applied to still others of the second plate electrode structures 945 included in the second capacitor structure, for example, a (4n−3)-th (n is a natural number) one of the second plate electrode structures 945.

Thus, four second capacitors 960 between the (4n−1)-th (n is a natural number) one of the second plate electrode structures 945 and (4n−3)-th (n is a natural number) one of the second plate electrode structures 945 may be electrically connected to each other through one second plate electrode structure 945 and two third plate electrode structures 970 therebetween, and a voltage corresponding to a difference between the source voltage V_{SS} and the drain voltage V_{DD} may be applied to the four second capacitors 960.

Thus, a capacitance of the second capacitor structure may have a quarter of the capacitance of the second capacitor structure of FIG. 8.

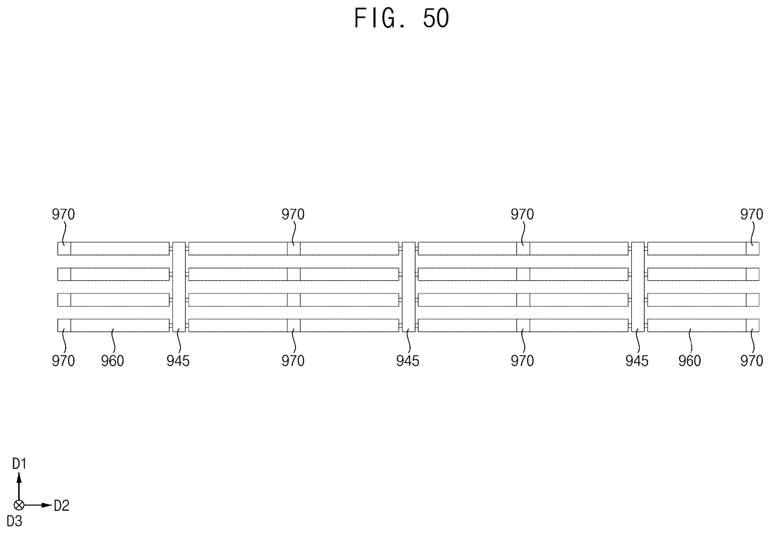

Referring to FIG. 50, the second plate electrode structure 945 included in the second capacitor structure may extend in the first direction D1, while a plurality of third plate electrode structures 970 included in the second capacitor structure may be spaced apart from each other in the first direction D1.

Thus, only a corresponding one of the second capacitors 960, instead of all of the second capacitors 960 disposed in the first direction D1, may be electrically connected to the third plate electrode structure 970.

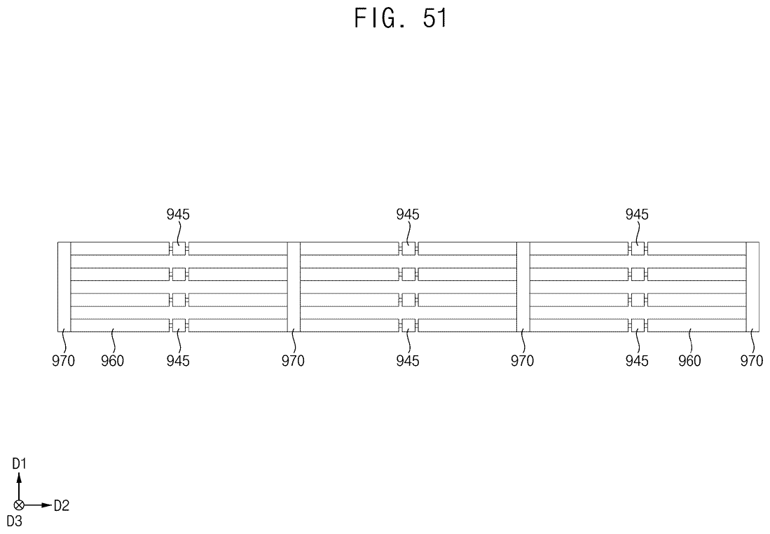

Referring to FIG. 51, the third plate electrode structure 970 included in the second capacitor structure may extend in the first direction D1, while a plurality of second plate electrode structures 945 included in the second capacitor structure may be spaced apart from each other in the first direction D1.

Thus, only a corresponding one of the second capacitors 960, instead of all of the second capacitors 960 disposed in the first direction D1, may be electrically connected to the second plate electrode structure 945.

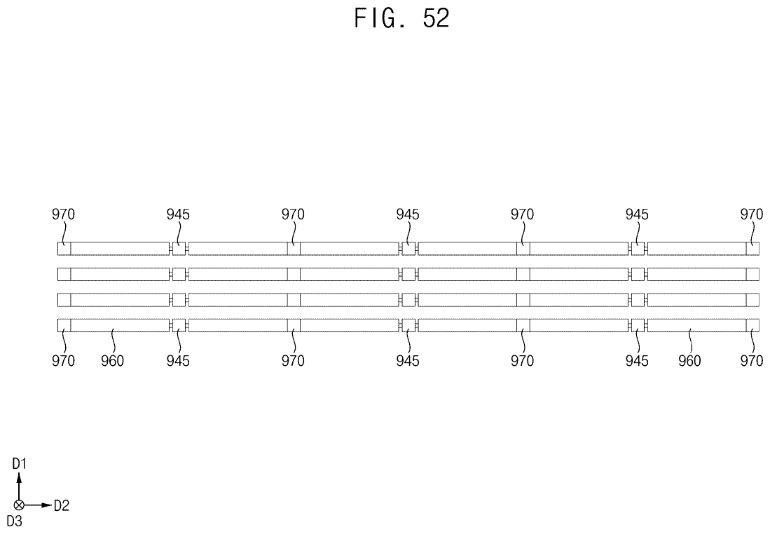

Referring to FIG. 52, a plurality of second plate electrode structures 945 included in the second capacitor structure may be spaced apart from each other in the first direction D1, and a plurality of third plate electrode structure 970 included in the second capacitor structure may be spaced apart from each other in the first direction D1.

Thus, only a corresponding one of the second capacitors 960, instead of all of the second capacitors 960 disposed in the first direction D1, may be electrically connected to each of the second and third plate electrode structures 945 and 970.

As illustrated above with reference to FIGS. 46 to 52, a voltage applied to the second and third plate electrode structures 945 and 970 included in the second capacitor structure, or the number of the second capacitors 960 electrically connected to the second and third plate electrode structures 945 and 970 may be adjusted, so that a capacitance of the second capacitor structure may have a desirable value.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. Further, as used herein, the term “and/or” includes any and all combinations of one or more of the associated listed items.

The foregoing is illustrative of example embodiments and is not to be construed as limiting thereof. Although a few example embodiments have been described, those skilled in the art will readily appreciate that many modifications are possible to the example embodiments without materially departing from the scope of the present disclosure. Accordingly, all such modifications are intended to be included within the scope of the present disclosure as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor device, comprising:
channels on a first region of a substrate, the channels being spaced apart from each other in a vertical direction perpendicular to an upper surface of the substrate, and the substrate including the first region and a second region;
a gate structure at least partially surrounding each of the channels;
a bit line in contact with a first end portion of each of the channels, the bit line extending in the vertical direction;
a first capacitor on a second end portion of each of the channels;
semiconductor patterns arranged in the vertical direction on the second region of the substrate, each of the semiconductor patterns at least partially overlapping a respective one of the channels in a horizontal direction parallel to the upper surface of the substrate; and
second capacitors on the semiconductor patterns, respectively.

2. The semiconductor device according to claim 1, wherein at least two of the second capacitors are electrically connected to each other.

3. The semiconductor device according to claim 2, further comprising:
a plate electrode structure extending in the vertical direction on the substrate, the plate electrode structure commonly contacting ones of the second capacitors.

4. The semiconductor device according to claim 3, wherein the plate electrode structure includes first, second, and third conductive patterns sequentially stacked in the vertical direction, and
wherein the first conductive pattern includes polysilicon doped with impurities, the second conductive pattern includes a metal silicide, and the third conductive pattern includes a metal.

5. The semiconductor device according to claim 3, further comprising:
an insulating layer structure that is between and contacts a sidewall of the plate electrode structure and a sidewall of each of the semiconductor patterns.

6. The semiconductor device according to claim 5, wherein the insulating layer structure includes a first insulating layer and a second insulating layer sequentially stacked in the horizontal direction on the sidewall of the plate electrode structure, and
wherein the first insulating layer includes an oxide, and the second insulating layer includes a nitride.

7. The semiconductor device according to claim 2, further comprising:
a plate electrode structure extending in the vertical direction on the substrate, the plate electrode structure being in contact with ones of the second capacitors.

8. The semiconductor device according to claim 7, wherein the plate electrode structure includes first, second, and third conductive patterns sequentially stacked in the vertical direction, and
wherein the first conductive pattern includes silicon-germanium doped with impurities, the second conductive pattern includes at least one of a metal silicide or a compound of a metal and silicon-germanium, and the third conductive pattern includes a metal.

9. The semiconductor device according to claim 7, wherein the plate electrode structure includes:
a vertical extension portion extending in the vertical direction; and
horizontal extension portions spaced apart from each other in the vertical direction, each of the horizontal extension portions extending in the horizontal direction.

10. The semiconductor device according to claim 9, wherein each of the horizontal extension portions of the plate electrode structure at least partially overlaps a respective one of the semiconductor patterns in the vertical direction.

11. The semiconductor device according to claim 1, further comprising:
a first metal silicide pattern between each of the channels and the first capacitor; and
a second metal silicide pattern between each of the semiconductor patterns and a respective one of the second capacitors.

12. The semiconductor device according to claim 1, wherein the first region of the substrate is a memory cell region, and the second region of the substrate is a peripheral circuit region.

13. The semiconductor device according to claim 1, wherein the first capacitor is a cell capacitor, and at least one of the second capacitors is a power capacitor.

14. A semiconductor device, comprising:
channels on a first region of a substrate, the channels being spaced apart from each other in a vertical direction perpendicular to an upper surface of the substrate, the substrate including the first region and a second region;
a gate structure at least partially surrounding each of the channels;
a bit line in contact with a first end portion of each of the channels, the bit line extending in the vertical direction;
a first capacitor on a second end portion of each of the channels;
a first plate electrode structure extending in the vertical direction on the second region of the substrate;
semiconductor patterns on opposite sidewalls of the first plate electrode structure in a first direction parallel to the upper surface of the substrate, at least two of the semiconductor patterns being spaced apart from each other in the vertical direction;
second capacitors each contacting a respective one of the opposite sidewalls of the first plate electrode structure and on upper and lower surfaces and a sidewall of at least one of the semiconductor patterns, each of the second capacitors extending in the vertical direction and including a first capacitor electrode, a dielectric pattern and a second capacitor electrode; and
second plate electrode structures on the opposite sidewalls, respectively, of the first plate electrode structure and on the second region of the substrate, each of the second plate electrode structures extending in the vertical direction and contacting a respective one of the second capacitors.

15. The semiconductor device according to claim 14, wherein the second capacitors and the second plate electrode structures are symmetrical in the first direction with respect to the first plate electrode structure.

16. The semiconductor device according to claim 14, wherein the first plate electrode structure is configured to receive a source voltage, and
wherein each of the second plate electrode structures is configured to receive a drain voltage.

17. The semiconductor device according to claim 14, wherein the first plate electrode structure, a first one of the second plate electrode structures and a first one of the second capacitors are included in a second capacitor structure, and
wherein the second capacitor structure is one of a plurality of second capacitor structures arranged in the first direction on the second region of the substrate, and the first plate electrode structure is one of a plurality of first plate electrode structures.

18. The semiconductor device according to claim 17, wherein each of the second plate electrode structures is in an electrically floating state,
wherein a first one of the plurality of first plate electrode structures is configured to receive a source voltage, and
wherein a second one of the plurality of first plate electrode structures is configured to receive a drain voltage.

19. The semiconductor device according to claim 14, wherein the first plate electrode structure extends in a second direction parallel to the upper surface of the substrate and intersecting the first direction,
wherein each of the second capacitors is one of a plurality of second capacitors spaced apart from each other in the second direction, the plurality of second capacitors contacting respective ones of the opposite sidewalls of the first plate electrode structure, and
wherein each of the second plate electrode structures is one of a plurality of second plate electrode structures spaced apart from each other in the second direction, the plurality of second plate electrode structures contacting respective ones of the plurality of second capacitors.

20. A semiconductor device, comprising:
channels on a memory cell region of a substrate, the channels being spaced apart from each other in a vertical direction perpendicular to an upper surface of the substrate, and the substrate including the memory cell region and a peripheral circuit region;
a gate structure at least partially surrounding each of the channels;
a bit line in contact with a first end portion of each of the channels, the bit line extending in the vertical direction;
a cell capacitor on a second end portion of each of the channels;
a first plate electrode structure extending in the vertical direction on the peripheral circuit region of the substrate;
semiconductor patterns on opposite sidewalls of the first plate electrode structure in a horizontal direction parallel to the upper surface of the substrate, at least two of the semiconductor patterns being spaced apart from each other in the vertical direction, and each of the semiconductor patterns at least partially overlapping a respective one of the channels in the horizontal direction;
a power capacitor in contact with at least one of the opposite sidewalls of the first plate electrode structure and on upper and lower surfaces and a sidewall of at least one of the semiconductor patterns, the power capacitor extending in the vertical direction and including a first capacitor electrode, a dielectric pattern and a second capacitor electrode; and
a second plate electrode structure on one of the opposite sidewalls of the first plate electrode structure and on the peripheral circuit region of the substrate, the second plate electrode structure extending in the vertical direction and contacting the second capacitor electrode of the power capacitor.
